(19) United States
(12) Patent Application Publication
(10) Pub. No.: US 2021/0013430 A1
(43) Pub. Date: Jan. 14, 2021

(54) ORGANIC ELECTROLUMINESCENCE DEVICE AND FUSED POLYCYCLIC COMPOUND FOR ORGANIC ELECTROLUMINESCENCE DEVICE

(71) Applicant: Samsung Display Co., Ltd., Yongin-si (KR)

(72) Inventors: Hyoyoung LEE, Suwon-si (KR); Soo-Byung KO, Yongin-si (KR); Junha PARK, Gwacheon-si (KR); Hankyu PAK, Suwon-si (KR); Jang Yeol BAEK, Yongin-si (KR); Mun-ki SIM, Seoul (KR); Chanseok OH, Seoul (KR)

(21) Appl. No.: 16/856,971

(22) Filed: Apr. 23, 2020

(30) Foreign Application Priority Data
Jul. 8, 2019 (KR) 10-2019-0082054

(51) Int. Cl. H01L 51/00

(52) U.S. Cl. CPC H01L 51/0082; H01L 51/5016; H01L 51/0085; H01L 51/0081

(57) ABSTRACT

An organic electroluminescence device of an embodiment includes a first electrode and a second electrode facing the first electrode, and a plurality of organic layers between the first electrode and the second electrode, wherein at least one selected from among the organic layers includes a fused polycyclic compound represented by Formula 1 below, thereby showing improved emission efficiency.

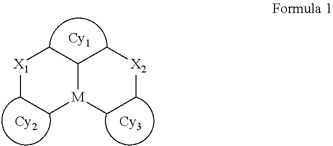

### CROSS-REFERENCE TO RELATED APPLICATION

This application claims priority to and the benefit of Korean Patent Application No. 10-2019-0082054, filed on Jul. 8, 2019, the entire contents of which are incorporated herein by reference.

### BACKGROUND

### 1. Field

Embodiments of the present disclosure relate to an organic electroluminescence device and a fused polycyclic compound used therein, and for example, to a fused polycyclic compound used as a light-emitting material and an organic electroluminescence device including the same.

### 2. Description of the Related Art

Recently, the development of an organic electroluminescence display device as an image display device is being actively conducted. Different from a liquid crystal display device, the organic electroluminescence display device is so-called a self-luminescent display device in which holes and electrons injected from a first electrode and a second electrode recombine in an emission layer, and a light-emitting material including an organic compound in the emission layer emits light to attain display.

In the application of an organic electroluminescence device to a display device, the decrease of the driving voltage, and the increase of the emission efficiency and the life of the organic electroluminescence device are desired, and developments on materials for an organic electroluminescence device stably attaining the requirements are being researched.

For example, recently, in order to accomplish an organic electroluminescence device with high efficiency, techniques on phosphorescence emission which uses energy in a triplet state or delayed fluorescence emission which uses the generating phenomenon of singlet excitons by the collision of triplet excitons (triplet-triplet annihilation, TTA) are being developed, and development on a material for thermally activated delayed fluorescence (TADF) using delayed fluorescence phenomenon is being conducted.

### SUMMARY

Embodiments of the present disclosure provide an organic electroluminescence device having improved emission efficiency.

Embodiments of the present disclosure also provide a fused polycyclic compound capable of improving the emission efficiency of an organic electroluminescence device.

An embodiment of the present disclosure provides an organic electroluminescence device including a first electrode, a second electrode located opposite to the first electrode, and a plurality of organic layers between the first electrode and the second electrode. At least one organic layer among the organic layers includes a fused polycyclic compound represented by the following Formula 1:

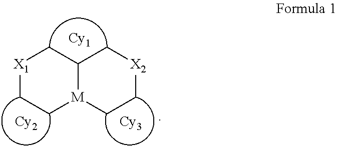

In Formula 1, M is Al, Ga, or In, X₁ and X₂ are each independently NR₁, O, S, P(═O)R₂, or P(═S)R₃, R₁ to R₃ are each independently a hydrogen atom, a deuterium atom, a halogen atom, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring, and Cy₁ to Cy₃ are each independently a substituted or unsubstituted aromatic hydrocarbon ring, a substituted or unsubstituted aromatic heterocycle, or combined with an adjacent group to form a ring.

In an embodiment, the organic layers may include a hole transport region on the first electrode, an emission layer on the hole transport region, and an electron transport region on the emission layer. The emission layer may include the fused polycyclic compound represented by Formula 1.

In an embodiment, the emission layer may emit delayed fluorescence.

In an embodiment, the emission layer may be a delayed fluorescence emission layer including a host and a dopant. The dopant may include the fused polycyclic compound represented by Formula 1.

In an embodiment, the emission layer may include a host having a first lowest triplet excitation energy level, a first dopant having a second lowest triplet excitation energy level which is lower than the first lowest triplet excitation energy level, and a second dopant having a third lowest triplet excitation energy level which is lower than the second lowest triplet excitation energy level. The first dopant may include the fused polycyclic compound represented by Formula 1.

In an embodiment, the first dopant may be a delayed fluorescence dopant. The second dopant may be a fluorescence dopant.

In an embodiment, the fused polycyclic compound represented by Formula 1 may be represented by the following Formula 2:

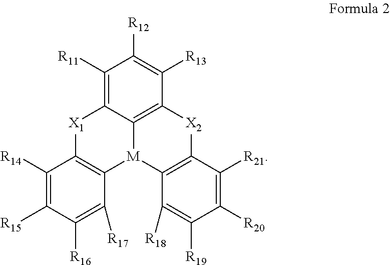

In Formula 2, R₁₁ to R₂₁ may be each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring.

In Formula 2, M, X₁, and X₂ may be the same as defined in Formula 1.

In an embodiment, at least one selected from among R₁₁ to R₂₁ may be a substituted or unsubstituted amine group, or a substituted or unsubstituted carbazole group.

In an embodiment, the fused polycyclic compound represented by Formula 2 may be represented by the following Formula 3:

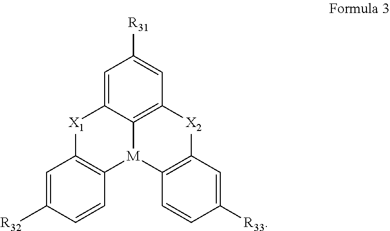

In Formula 3, R₃₁ to R₃₃ are each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring, and at least one selected from among R₃₁ to R₃₃ is a substituted or unsubstituted amine group, or a substituted or unsubstituted carbazole group.

In Formula 3, M, X₁, and X₂ are the same as defined in Formula 1.

In an embodiment, at least one selected from among R₃₁ to R₃₃ may be represented by the following Formula 4-1 or Formula 4-2:

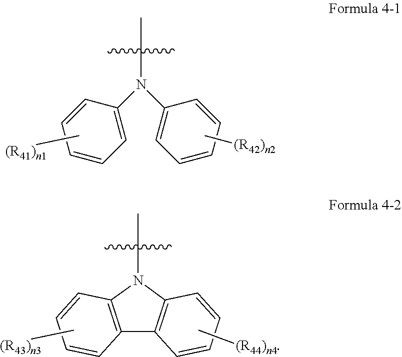

In Formulae 4-1 and 4-2, R₄₁ to R₄₄ are each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring, n₁ and n₂ are each independently an integer of 0 to 5, and n₃ and n₄ are each independently an integer of 0 to 4.

In an embodiment, X₁ and X₂ may be each independently NR₁, or O, and R₁ may be a substituted or unsubstituted phenyl group.

In an embodiment, the first electrode and the second electrode may each independently include at least one selected from Ag, Mg, Cu, Al, Pt, Pd, Au, Ni, Nd, Ir, Cr, Li, Ca, LiF/Ca, LiF/Al, Mo, Ti, In, Sn, Zn, a compound of two or more thereof, a mixture of two or more thereof, and oxides of one or more thereof.

In an embodiment of the present disclosure, a fused polycyclic compound according to an embodiment may be represented by Formula 1 shown above.

### BRIEF DESCRIPTION OF THE FIGURES

The accompanying drawings are included to provide a further understanding of the subject matter of the present disclosure, and are incorporated in and constitute a part of this specification. The drawings illustrate exemplary embodiments of the present disclosure and, together with the description, serve to explain principles of the present disclosure. In the drawings:

FIG. 1 is a cross-sectional view schematically illustrating an organic electroluminescence device according to an embodiment of the present disclosure;

FIG. 2 is a cross-sectional view schematically illustrating an organic electroluminescence device according to an embodiment of the present disclosure;

FIG. 3 is a cross-sectional view schematically illustrating an organic electroluminescence device according to an embodiment of the present disclosure; and

FIG. 4 is a cross-sectional view schematically illustrating an organic electroluminescence device according to an embodiment of the present disclosure.

### DETAILED DESCRIPTION

The above-described features of embodiments of the present disclosure will be easily understood from the disclosed exemplary embodiments with reference to the accompanying drawings. The subject matter of the present disclosure may, however, be embodied in different forms and should not be construed as limited to the embodiments set forth herein. Rather, exemplary embodiments are provided so that the contents disclosed herein are thorough and complete, and the spirit of the present disclosure is sufficiently described for a person skilled in the art.

Like reference numerals refer to like elements for explaining each drawing. In the drawings, the sizes of elements may be enlarged for clarity of the present disclosure. It will be understood that, although the terms first, second, etc. may be used herein to describe various elements, these elements should not be limited by these terms. These terms are only used to distinguish one element from another element. For example, a first element discussed below could be termed a second element, and similarly, a second element could be termed a first element. As used herein, the singular forms are intended to include the plural forms as well, unless the context clearly indicates otherwise.

It will be further understood that the terms “comprises” or “comprising,” when used in this specification, specify the presence of stated features, numerals, steps, operations, elements, parts, or a combination thereof, but do not preclude the presence or addition of one or more other features, numerals, steps, operations, elements, parts, or a combination thereof. It will also be understood that when a layer, a film, a region, a plate, etc. is referred to as being “on” another part, it can be “directly on” the other part, or intervening layers may also be present. On the contrary, when a layer, a film, a region, a plate, etc. is referred to as being “under” another part, it can be “directly under” the other part, or intervening layers may also be present.

Hereinafter, the organic electroluminescence device according to an embodiment of the present disclosure and a fused polycyclic compound of an embodiment included therein will be explained with reference to the attached drawings.

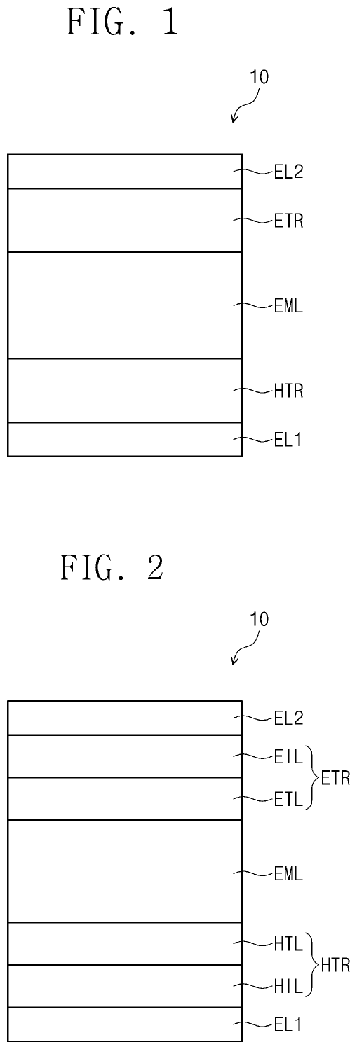

FIGS. 1 to 4 are cross-sectional views schematically showing organic electroluminescence devices according to exemplary embodiments of the present disclosure. Referring to FIGS. 1 to 4, in an organic electroluminescence device 10 according to an embodiment, a first electrode EL1 and a second electrode EL2 are oppositely located (e.g., face each other), and a plurality of organic layers may be between the first electrode EL1 and the second electrode EL2. The plurality of the organic layers may include a hole transport region HTR, an emission layer EML and an electron transport region ETR. For example, the organic electroluminescence device 10 of an embodiment may include a first electrode EL1, a hole transport region HTR, an emission layer EML, an electron transport region ETR, and a second electrode, laminated one by one. A capping layer CPL may be on the second electrode EL2.

The organic electroluminescence device 10 of an embodiment may include a fused polycyclic compound of an embodiment, which will be explained in more detail below, in at least one organic layer among the plurality of the organic layers between the first electrode EL1 and the second electrode EL2. For example, the organic electroluminescence device 10 of an embodiment may include a fused polycyclic compound of an embodiment in the emission layer EML between the first electrode EL1 and the second electrode EL2. However, an embodiment of the present disclosure is not limited thereto. For example, the organic electroluminescence device 10 of an embodiment may include a fused polycyclic compound of an embodiment in at least one organic layer included in the hole transport region HTR and the electron transport region ETR, which may be included among the plurality of the organic layers (in addition to the emission layer EML) between the first electrode EL1 and the second electrode EL2. In some embodiments, the organic electroluminescence device 10 of an embodiment may include a fused polycyclic compound of an embodiment in the capping layer CPL on the second electrode EL2.

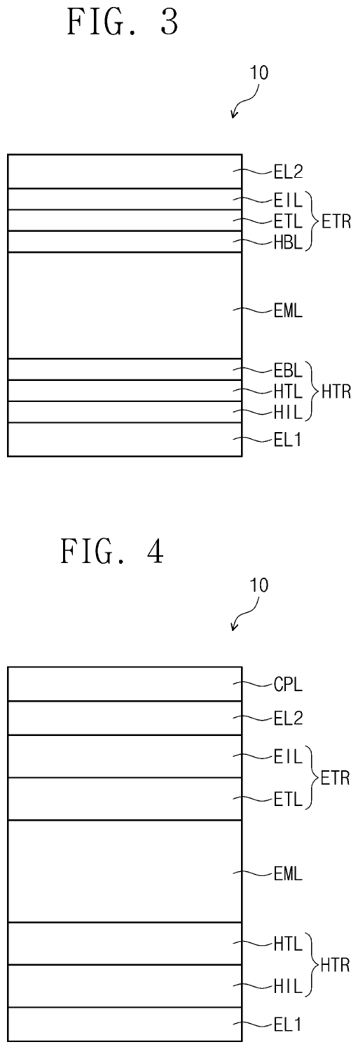

When compared with FIG. 1, FIG. 2 shows the cross-sectional view of an organic electroluminescence device 10 of an embodiment, wherein a hole transport region HTR includes a hole injection layer HIL and a hole transport layer HTL, and an electron transport region ETR includes an electron injection layer EIL and an electron transport layer ETL. In addition, when compared with FIG. 1, FIG. 3 shows the cross-sectional view of an organic electroluminescence device 10 of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared with FIG. 1, FIG. 4 shows the cross-sectional view of an organic electroluminescence device 10 of an embodiment including a capping layer CPL on the second electrode EL2.

Hereinafter, in explaining the organic electroluminescence device 10 of an embodiment, the emission layer EML is explained to include a fused polycyclic compound according to an embodiment, but an embodiment of the present disclosure is not limited thereto. For example, the fused polycyclic compound according to an embodiment may be included in a hole transport region HTR, electron transport region ETR, and/or capping layer CPL.

The first electrode EL1 has conductivity (e.g., electrical conductivity). The first electrode EL1 may be formed using a metal alloy or a conductive compound. The first electrode EL1 may be an anode. The first electrode EL1 may be a pixel electrode. The first electrode EL1 may be a transmissive electrode, a transflective electrode, or a reflective electrode. If the first electrode EL1 is the transmissive electrode, the first electrode EL1 may be formed using a transparent metal oxide such as indium tin oxide (ITO), indium zinc oxide (IZO), zinc oxide (ZnO), and indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). Also, the first electrode EL1 may have a structure including a plurality of layers including a reflective layer or a transflective layer formed using the above-described materials, and a transmissive conductive layer formed using ITO, IZO, ZnO, and/or ITZO. For example, the first electrode EL1 may include a three-layer structure of ITO/Ag/ITO. However, an embodiment of the present disclosure is not limited thereto. The thickness of the first electrode EL1 may be from about 1,000 Å to about 10,000 Å, for example, from about 1,000 Å to about 3,000 Å.

The hole transport region HTR is provided on the first electrode EL1. The hole transport region HTR may include at least one selected from a hole injection layer HIL, a hole transport layer HTL, a hole buffer layer, and an electron blocking layer EBL. The thickness of the hole transport region HTR may be from about 50 Å to about 1,500 Å

The hole transport region HTR may have a single layer formed using a single material, a single layer formed using a plurality of different materials, or a multilayer structure including a plurality of layers formed using a plurality of different materials.

For example, the hole transport region HTR may have the structure of a single layer of a hole injection layer HIL, or a hole transport layer HTL, and may have a structure of a single layer formed using a hole injection material and a hole transport material. In some embodiments, the hole transport region HTR may have a structure of a single layer formed using a plurality of different materials, or a structure laminated from the first electrode EL1 of hole injection layer HIL/hole transport layer HTL, hole injection layer HIL/hole transport layer HTL/hole buffer layer, hole injection layer HIL/hole buffer layer, hole transport layer HTL/hole buffer layer, or hole injection layer HIL/hole transport layer HTL/electron blocking layer EBL, without limitation.

The hole transport region HTR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The hole injection layer HIL may include, for example, a phthalocyanine compound such as copper phthalocyanine, N,N′-diphenyl-N,N′-bis-[4-(phenyl-m-tolyl-amino)-phenyl]-phenyl-4,4′-diamine (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris{N,-2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), N,N′-di(1-naphthyl)-N,N″-diphenyl-(1,1″-biphenyl)-4,4″-diamine (NPD), triphenylamine-containingpolyetherketone (TPAPEK), 4-isopropyl-4′-methyldiphenyliodonium [tetrakis(pentafluorophenyl)borate], and/ordipyrazino[2,3-f:2′,3′-h]quinoxaline-2,3,6,7,10,11-hexacarbonitrile (HAT-CN).

The hole transport layer HTL may include, for example, carbazole derivatives such as N-phenyl carbazole and polyvinyl carbazole, fluorene-based derivatives, N,N′-bis(3-methylphenyl)-N,N′-diphenyl-[1,1-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl)benzeneamine (TAPC), 4,4′-bis[N,N′-(3-tolyl)amino]-3,3′-dimethylbiphenyl (HMTPD), 1,3-bis(N-carbazolyl)benzene (mCP), 9-(4-tert-butylphenyl)-3,6-bis(triphenylsilyl)-9H-carbazole (CzSi), and/or the like.

The thickness of the hole transport region HTR may be from about 100 Å to about 10,000 Å, for example, from about 100 Å to about 5,000 Å. The thickness of the hole injection region HIL may be, for example, from about 30 Å to about 1,000 Å, and the thickness of the hole transport layer HTL may be from about 30 Å to about 1,000 Å. For example, the thickness of the electron blocking layer EBL may be from about 10 Å to about 1,000 Å. If the thicknesses of the hole transport region HTR, the hole injection layer HIL, the hole transport layer HTL and the electron blocking layer EBL satisfy the above-described ranges, suitable or satisfactory hole transport properties may be achieved without substantial increase of a driving voltage.

The hole transport region HTR may further include a charge generating material in addition to the above-described materials to increase conductivity (e.g., electrical conductivity). The charge generating material may be dispersed uniformly or non-uniformly in the hole transport region HTR. The charge generating material may be, for example, a p-dopant. The p-dopant may be one of quinone derivatives, metal oxides, and/or cyano group-containing compounds, without limitation. For example, non-limiting examples of the p-dopant may include quinone derivatives such as tetracyanoquinodimethane (TCNQ) and 2,3,5,6-tetrafluoro-7,7′,8,8′-tetracyanoquinodimethane (F4-TCNQ), metal oxides such as tungsten oxide, and molybdenum oxide, without limitation.

As described herein above, the hole transport region HTR may further include at least one of a hole buffer layer or an electron blocking layer EBL in addition to the hole injection layer HIL and the hole transport layer HTL. The hole buffer layer may compensate an optical resonance distance according to the wavelength of light emitted from an emission layer EML and may increase light emission efficiency. Materials which may be included in a hole transport region HTR may be used as materials included in a hole buffer layer. The electron blocking layer EBL is a layer prevents or reduces the injection of electrons from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed using a single material, a single layer formed using a plurality of different materials, or a multilayer structure having a plurality of layers formed using a plurality of different materials.

In the organic electroluminescence device 10 of an embodiment, the emission layer EML may include the fused polycyclic compound of an embodiment.

In the present description, the symbol

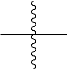

means a connecting part.

In the present description, the term “substituted or unsubstituted” corresponds to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkoxy group, a hydrocarbon ring group, an aryl group, and a heterocyclic group. In addition, each of the exemplified substituents may be substituted or unsubstituted. For example, a biphenyl group may be interpreted as an aryl group or a phenyl group substituted with a phenyl group.

In the present description, the statement “forming a ring via the combination with an adjacent group” may mean forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The ring formed by the combination with an adjacent group may be a monocyclic ring or a polycyclic ring. In addition, the ring formed via the combination with an adjacent group may be combined with another ring to form a spiro structure.

In the present description, the term “adjacent group” may mean a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other.

In the present description, the halogen atom may be a fluorine atom, a chlorine atom, a bromine atom, or an iodine atom.

In the present description, the alkyl may be a linear, branched or cyclic type (e.g., may be a linear, branched, or cyclic alkyl group). The carbon number of the alkyl may be 1 to 50, 1 to 30, 1 to 20, 1 to 10, or 1 to 6. Examples of the alkyl may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the present description, the hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic.

In the present description, the hydrocarbon ring may be an optional functional group or substituted, which is derived from an aliphatic hydrocarbon ring, or an optional functional group or substituent derived from an aromatic hydrocarbon ring. The carbon number of the hydrocarbon ring for forming a ring may be 5 to 60.

In the present description, the heterocyclic group may be an optional functional group or substituent, which is derived from a heterocycle including at least one heteroatom as a ring-forming element. The carbon number of the heterocyclic group for forming a ring may be 5 to 60 (or 1 to 60).

In the present description, the aryl group means an optional functional group or substituent derived from an aromatic hydrocarbon ring. The aryl group may be a monocyclic aryl group or a polycyclic aryl group. The carbon number for forming a ring in the aryl group may be 6 to 60, 6 to 30, 6 to 20, or 6 to 15. Examples of the aryl group may include phenyl, naphthyl, fluorenyl, anthracenyl, phenanthryl, biphenyl, terphenyl, quaterphenyl, quinqphenyl, sexiphenyl, triphenylenyl, pyrenyl, benzofluoranthenyl, chrysenyl, etc., without limitation.

In the present description, the fluorenyl group may be substituted, and two substituents may be combined with each other to form a spiro structure. Examples of a substituted fluorenyl group are as follows. However, an embodiment of the present disclosure is not limited thereto.

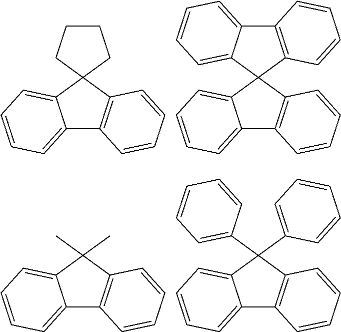

In the present description, the heteroaryl may be one including one or more selected from among B, O, N, P, Si and S as heteroatoms. If the heteroaryl includes two or more heteroatoms, two or more heteroatoms may be the same or different. The heteroaryl may be monocyclic heteroaryl or polycyclic heteroaryl. The carbon number for forming a ring of the heteroaryl may be 2 to 60 (or 1 to 60), 2 to 30, 2 to 20, or 2 to 10. Examples of the heteroaryl may include thiophene, furan, pyrrole, imidazole, thiazole, oxazole, oxadiazole, triazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isooxazole, oxadiazole, thiadiazole, phenothiazine, dibenzosilole, dibenzofuran, etc., without limitation.

In the present description, the silyl group includes an alkylsilyl group and an arylsilyl group. Examples of the silyl group may include trimethylsilyl, triethylsilyl, t-butyldimethylsilyl, vinyldimethylsilyl, propyldimethylsilyl, triphenylsilyl, diphenylsilyl, phenylsilyl, etc. However, an embodiment of the present disclosure is not limited thereto.

In the present description, the boron group includes an alkyl boron group and an aryl boron group. Examples of the boron group include a trimethylboron group, a triethylboron group, a t-butyldimethylboron group, a triphenylboron group, a diphenylboron group, a phenylboron group, etc., without limitation.

In the present description, the carbon number of the amine group is not specifically limited, but may be 1 to 30. The amine group may include an alkyl amine group and an aryl amine group. Examples of the amine group include a methylamine group, a dimethylamine group, a phenylamine group, a naphthylamine group, a 9-methyl-anthracenylamine group, a triphenylamine group, etc., without limitation

In the present description, the hydrocarbon ring means an optional functional group or substituent derived from an aliphatic hydrocarbon ring. The hydrocarbon ring may be a saturated hydrocarbon ring of 5 to 20 carbon atoms for forming a ring.

In the present description, the heterocyclic group may include one or more selected from among B, O, N, P, Si, and S as heteroatoms. If the heterocyclic group includes two or more heteroatoms, two or more heteroatoms may be the same or different. The heterocyclic group may be monocyclic heterocyclic group or polycyclic heterocyclic group, and has the concept including a heteroaryl group. The carbon number for forming a ring of the heterocyclic group may be 2 to 30 (or 1 to 30), 2 to 20, or 2 to 10.

The fused polycyclic compound of an embodiment is represented by the following Formula 1:

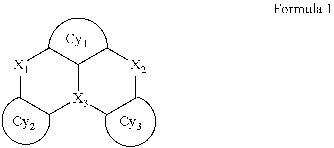

In Formula 1, M may be any one selected from among elements in group 13 excluding boron (B) (e.g., group 13 of the Periodic Table of elements, except for boron). For example, M may be Al, Ga, or In.

In Formula 1, X₁ and X₂ are each independently NR₁, O, S, P(═O)R₂, or P(═S)R₃. R₁ to R₃ are each independently a hydrogen atom, a deuterium atom, a halogen atom, a substituted or unsubstituted alkyl group of 1 to 20 carbon atoms, a substituted or unsubstituted aryl group of 6 to 60 carbon atoms for forming a ring, or a substituted or unsubstituted heteroaryl group of 2 to 60 carbon atoms for forming a ring. Otherwise, R₁ to R₃ may be each independently combined with an adjacent group to form a ring. In an embodiment, X₁ and X₂ may be each independently NR₁, or O. For example, in the fused polycyclic compound of an embodiment, represented by Formula 1, both X₁ and X₂ may be NR₁. Otherwise, both X₁ and X₂ may be O. Otherwise, any one selected from among X₁ and X₂ may be NR₁ and the remainder may be O. In case where at least one selected from among X₁ and X₂ is NR₁, R₁ may be a substituted or unsubstituted phenyl group. For example, R₁ may be an unsubstituted phenyl group. Otherwise, R₁ may be a 1,3,5-trimethylphenyl group.

In Formula 1, Cy₁ to Cy₃ are each independently a substituted or unsubstituted aromatic hydrocarbon ring, or a substituted or unsubstituted aromatic heterocycle. Cy₁ to Cy₃ may be each independently a five- or six-member substituted or unsubstituted aromatic hydrocarbon ring, or a substituted or unsubstituted aromatic heterocycle. Otherwise, Cy₁ to Cy₃ may be each independently combined with an adjacent group to form an additional ring. For example, Cy₁ to Cy₃ may be each independently a substituted or unsubstituted six-member aromatic hydrocarbon ring.

In the fused polycyclic compound of an embodiment, M is Al, Ga, or In, which are selected from among the elements in group 13 (e.g., group 13 of the Periodic Table). Group 13 of the Periodic Table is the same group as boron (B), which is a ring-forming central atom which forms a fused ring corresponding to a core of an existing compound. The fused polycyclic compound of an embodiment of the present disclosure shows multiple resonances due to a plurality of aromatic rings forming fused rings to easily separate HOMO and LUMO states in one molecule. Accordingly, the fused polycyclic compound of an embodiment may be used as a material configured to emit delayed fluorescence. In the fused polycyclic compound of an embodiment, M includes Al, Ga or In, which are relatively large-sized atoms selected from among the elements in group 13 (e.g., group 13 of the Periodic Table of elements) as a ring-forming central atom, when compared with existing polycyclic compounds including B as a ring-forming central atom. The difference (AEST) between the lowest triplet excitation energy level (T1 level) and the lowest singlet excitation energy level (S1 level) may be decreased in the fused polycyclic compound of an embodiment as compared to existing polycyclic compounds including B as a ring-forming central atom. Accordingly, if the fused polycyclic compound of an embodiment is used as a material for emitting delayed florescence, the emission efficiency of an organic electroluminescence device may be even further improved.

The fused polycyclic compound represented by Formula 1 may be represented by the following Formula 2:

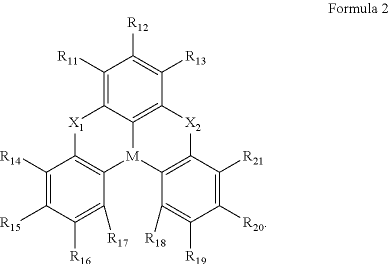

In Formula 2, R₁₁ to R₂₁ may be each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, or a substituted or unsubstituted heteroaryl group of 2 to 60 carbon atoms for forming a ring. Otherwise, R₁₁ to R₂₁ may be each independently combined with an adjacent group to form an additional ring. At least one selected from among R₁₁ to R₂₁ may be a substituted or unsubstituted amine group, or a substituted or unsubstituted carbazole group. For example, at least one selected from among R₁₂, R₁₅, and R₂₀ may be a substituted or unsubstituted amine group, or a substituted or unsubstituted carbazole group. At least one selected from among R₁₂, R₁₅, and R₂₀ may be a substituted or unsubstituted N,N-diphenylamine group, or a substituted or unsubstituted carbazole group.

In Formula 2, the same explanation for M, X₁, and X₂ with respect to Formula 1 may be applied.

The fused polycyclic compound represented by Formula 2 may be represented by the following Formula 3:

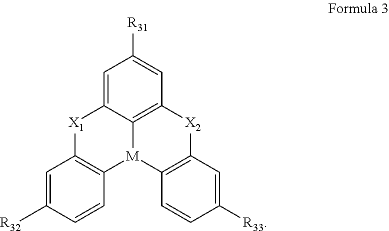

In Formula 3, R₃₁ to R₃₃ may be each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, or a substituted or unsubstituted heteroaryl group of 2 to 60 carbon atoms for forming a ring. Otherwise, R₃₁ to R₃₃ may be each independently combined with an adjacent group to form an additional ring. At least one selected from among R₃₁ to R₃₃ may be a substituted or unsubstituted amine group, or a substituted or unsubstituted carbazole group. For example, at least one selected from among R₃₁ to R₃₃ may be a substituted or unsubstituted N,N-diphenylamine group, or a substituted or unsubstituted carbazole group.

In Formula 3, the same explanation for M, X₁, and X₂ with respect to Formula 1 may be applied.

In Formula 3, at least one selected from among R₃₁ to R₃₃ may be represented by the following Formula 4-1 or Formula 4-2:

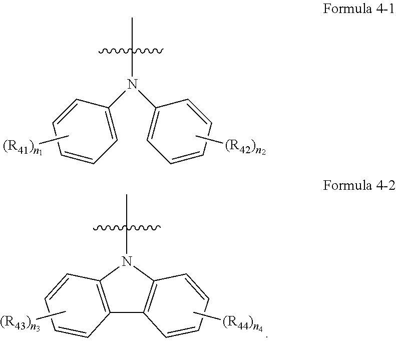

In Formulae 4-1 and 4-2, R₄₁ to R₄₄ may be each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, or a substituted or unsubstituted heteroaryl group of 2 to 60 carbon atoms for forming a ring. Otherwise, R₄₁ to R₄₄ may be each independently combined with an adjacent group to form an additional ring. For example, R₄₁ to R₄₄ may be each independently a hydrogen atom, a substituted or unsubstituted N,N-diphenylamine group, or a substituted or unsubstituted carbazole group.

n₁ and n₂ may be each independently an integer of 0 to 5. In Formula 4-1, if n₁ is 0, the fused polycyclic compound according to an embodiment may not be substituted with R₄₁. Formula 4-1 in which n₁ is 5 and all R₄₁ groups are hydrogen atoms, may be the same as Formula 4-1 in which n₁ is 0. In Formula 4-1, if n₁ is an integer of 2 or more, a plurality of R₄₁ groups may be the same or at least one selected from among the plurality of R₄₁ groups may be different. In Formula 4-1, if n₂ is 0, the fused polycyclic compound according to an embodiment may not be substituted with R₄₂. Formula 4-1 in which n₂ is 5 and all R₄₂ groups are hydrogen atoms, may be the same as Formula 4-1 in which n₂ is 0. In Formula 4-1, if n₂ is an integer of 2 or more, a plurality of R₄₂ groups may be the same or at least one selected from among the plurality of R₄₂ groups may be different. In Formula 4-2, if n₃ is 0, the fused polycyclic compound according to an embodiment may not be substituted with R₄₃. Formula 4-2 in which n₃ is 5 and all R₄₃ groups are hydrogen atoms, may be the same as Formula 4-2 in which n₃ is 0. In Formula 4-2, if n₃ is an integer of 2 or more, a plurality of R₄₃ groups may be the same or at least one selected from among the plurality of R₄₃ groups may be different. In Formula 4-2, if n₄ is 0, the fused polycyclic compound according to an embodiment may not be substituted with R₄₄. Formula 4-2 in which n₄ is 5 and all R₄₄ groups are hydrogen atoms, may be the same as Formula 4-2 in which n₄ is 0. In Formula 4-2, if n₄ is an integer of 2 or more, a plurality of R₄₄ groups may be the same or at least one selected from among the plurality of R₄₄ groups may be different.

The fused polycyclic compound of an embodiment may be any one selected from among the compounds represented in Compound Group 1 below. The organic electroluminescence device 10 of an embodiment may include at least one fused polycyclic compound selected from among the compounds represented in Compound Group 1 in an emission layer EML.

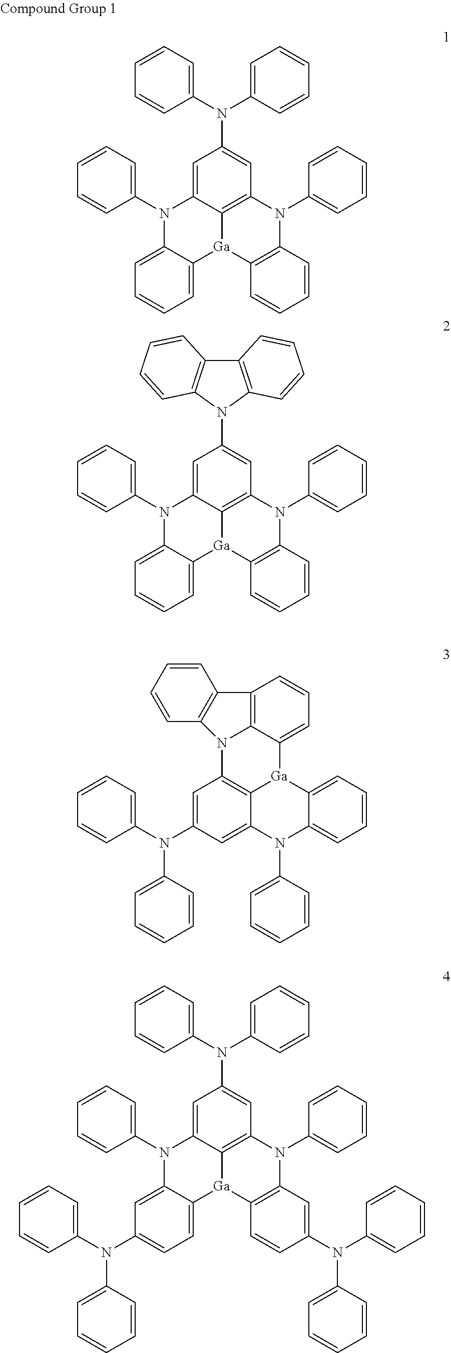

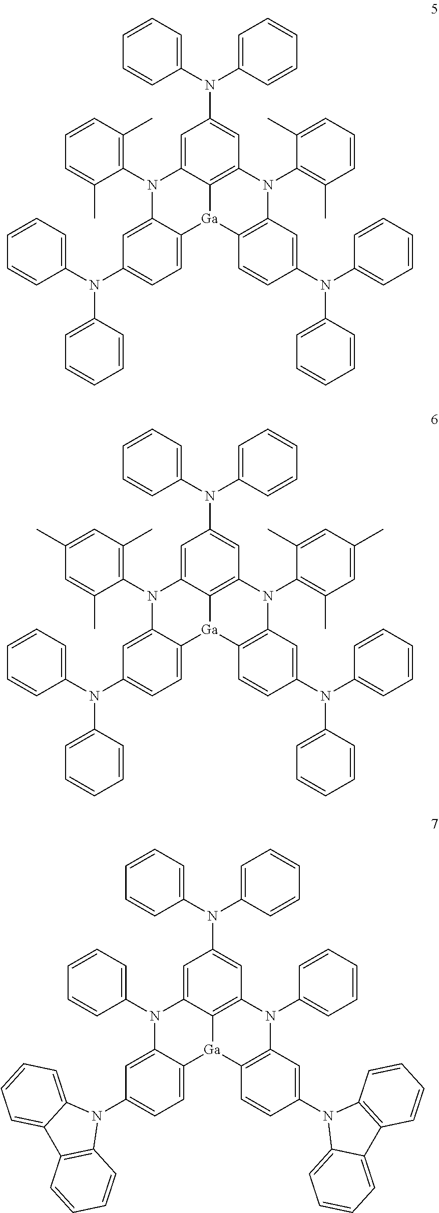

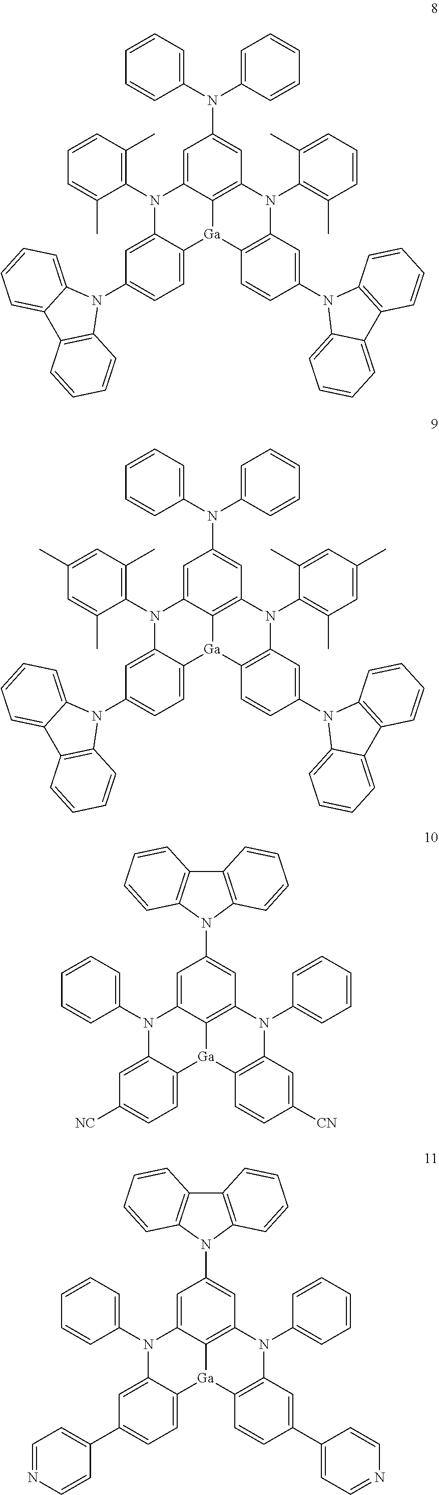

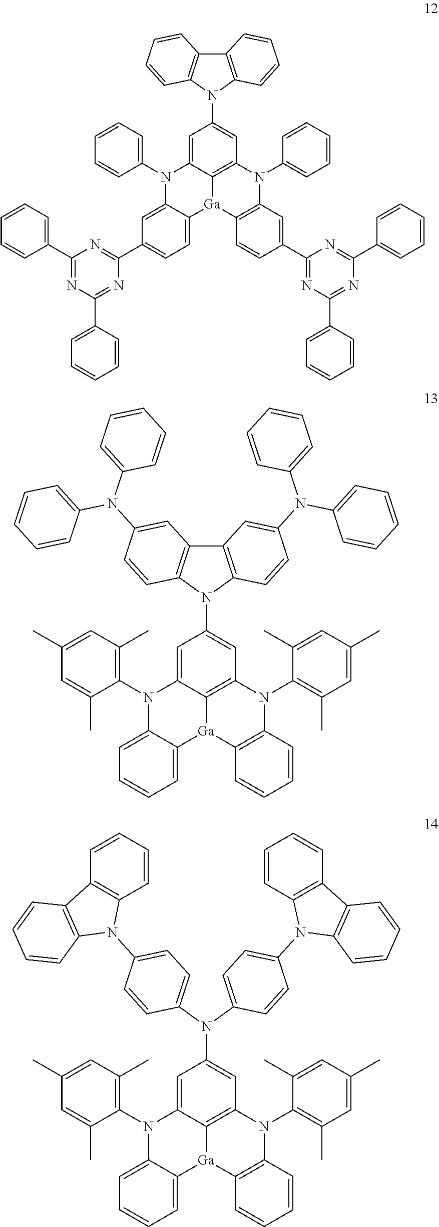

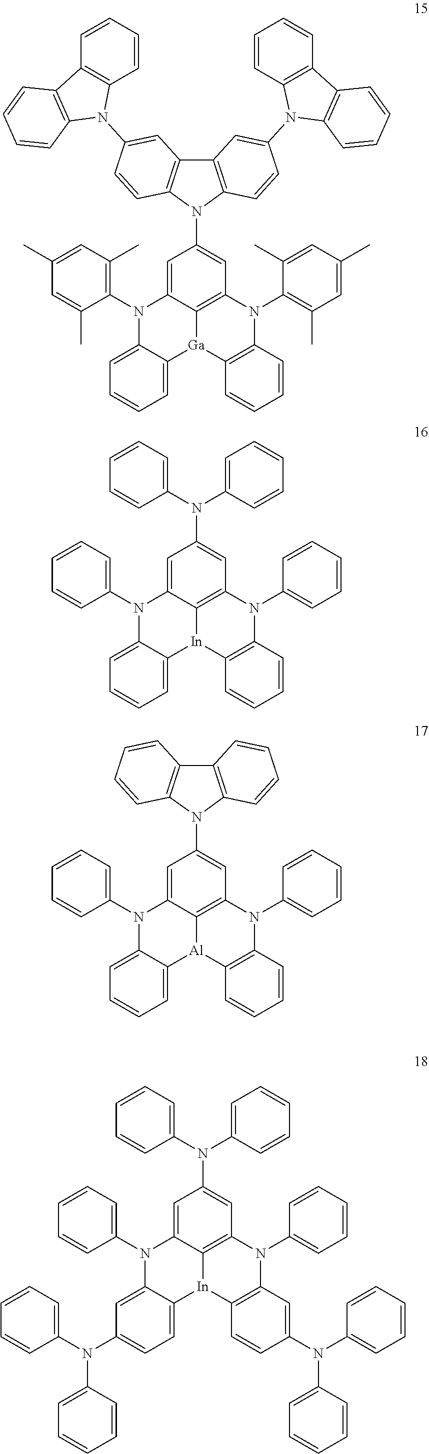

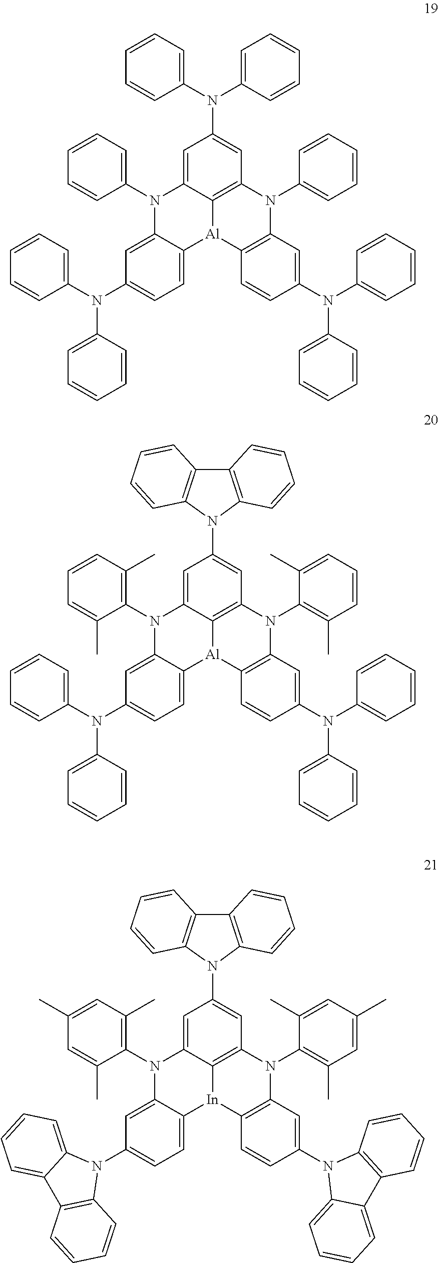

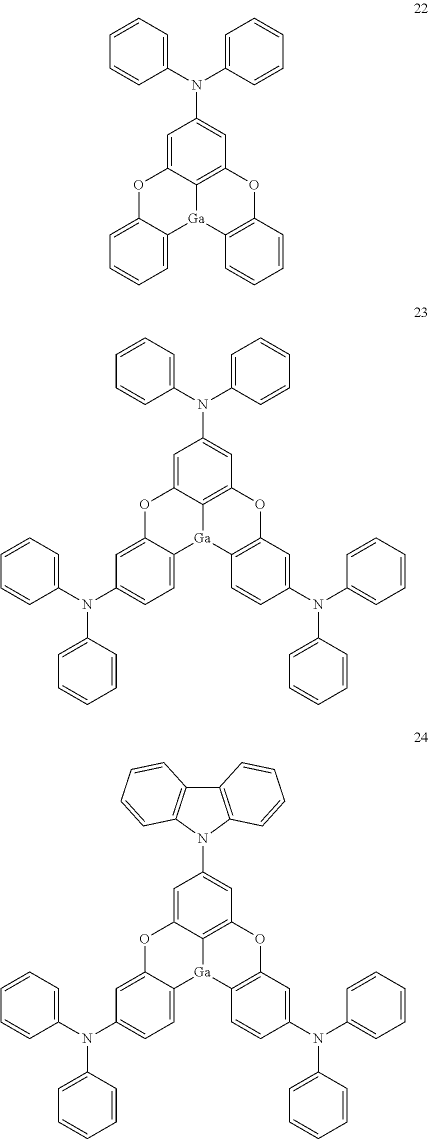

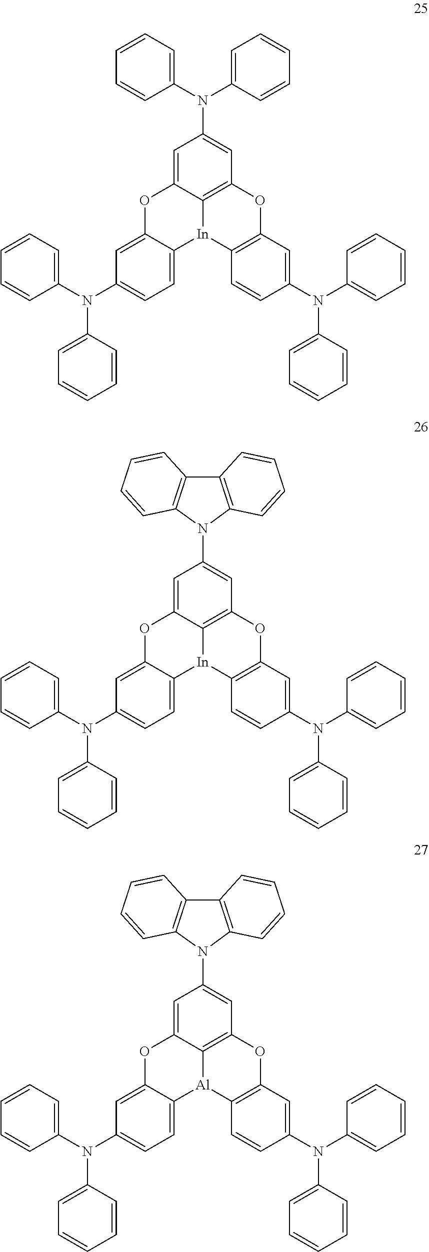

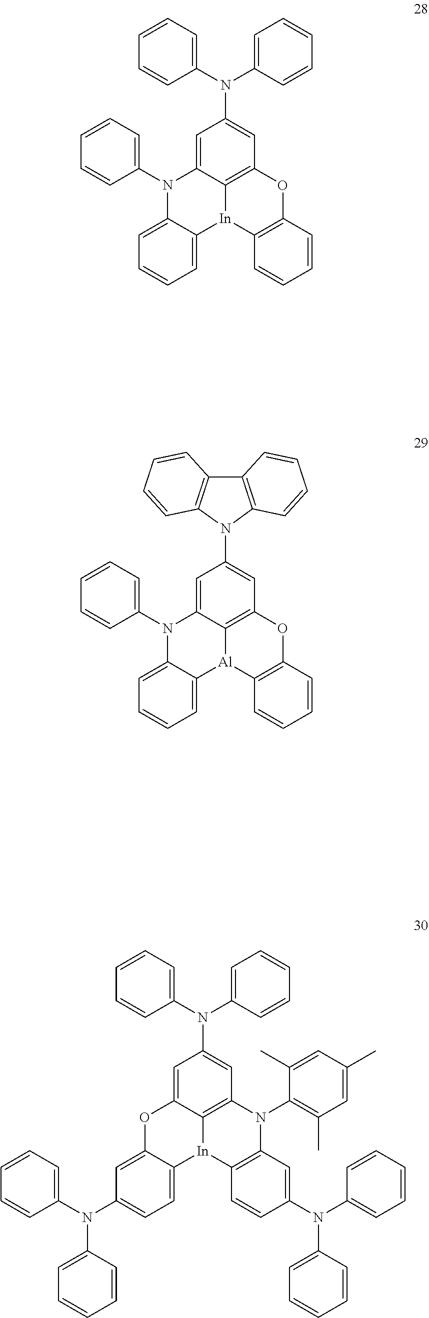

The fused polycyclic compound of an embodiment, represented by Formula 1 may be a thermally activated delayed fluorescence emission material. In addition, the fused polycyclic compound of an embodiment, represented by Formula 1 may be a thermally activated delayed fluorescence dopant having a difference (DEST) between the lowest triplet excitation energy level (T1 level) and the lowest singlet excitation energy level (S1 level) of about 0.33 eV or less.

The fused polycyclic compound of an embodiment, represented by Formula 1 may be a light-emitting material having a light-emitting central wavelength in a wavelength region of about 430 nm to about 490 nm. For example, the fused polycyclic compound of an embodiment, represented by Formula 1 may be a blue thermally activated delayed fluorescence (TADF) dopant (e.g., may be configured to emit blue light by way of thermally activated delayed fluorescence). However, an embodiment of the present disclosure is not limited thereto, and in case of using the fused polycyclic compound of an embodiment as the light-emitting material, the fused polycyclic compound may be used as a dopant material emitting light in various suitable wavelength regions, such as a red emitting dopant and a green emitting dopant.

In the organic electroluminescence device 10 of an embodiment, the emission layer EML may emit delayed fluorescence. For example, the emission layer EML may emit thermally activated delayed fluorescence (TADF).

In addition, the organic electroluminescence device 10 may emit blue light. For example, the emission layer EML of the organic electroluminescence device 10 of an embodiment may emit blue light in a region of about 490 nm or more. However, an embodiment of the present disclosure is not limited thereto, and the emission layer EML may emit green light or red light.

The organic electroluminescence device 10 of an embodiment may include a plurality of emission layers. The plurality of emission layers may be laminated one by one and provided. For example, the organic electroluminescence device 10 including a plurality of emission layers may emit white light. The organic electroluminescence device including the plurality of emission layers may be an organic electroluminescence device having a tandem structure. If the organic electroluminescence device 10 includes a plurality of emission layers, at least one emission layer EML may include the fused polycyclic compound of an embodiment.

In an embodiment, the emission layer EML includes a host and a dopant, and may include the fused polycyclic compound of an embodiment as a dopant. For example, in the organic electroluminescence device 10 of an embodiment, the emission layer EML may include a host for emitting delayed fluorescence and a dopant for emitting delayed fluorescence, and may include the fused polycyclic compound as a dopant for emitting delayed fluorescence. The emission layer EML may include at least one selected from among the fused polycyclic compounds represented in Compound Group 1 as a thermally activated delayed fluorescence dopant.

In an embodiment, the emission layer EML may be a delayed fluorescence emission layer, and the emission layer EML may include any suitable host material available in the art and the above-described fused polycyclic compound. For example, in an embodiment, the fused polycyclic compound may be used as a TADF dopant.

As the host material of the emission layer EML, any suitable materials available in the art may be used, and may be selected, without specific limitation, from fluoranthene derivatives, pyrene derivatives, arylacetylene derivatives, anthracene derivatives, fluorene derivatives, perylene derivatives, chrysene derivatives, or the like.

In some embodiments, pyrene derivatives, perylene derivatives, and anthracene derivatives may be used. For example, as the host material of the emission layer EML, anthracene derivatives represented by the following Formula 5 may be used:

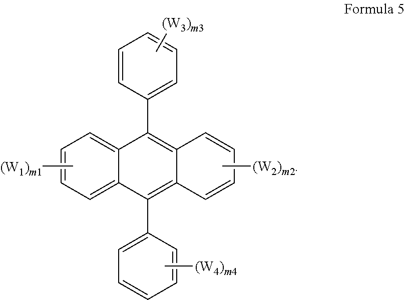

In Formula 5, W₁ to W₄ may be each independently a hydrogen atom, a deuterium atom, a halogen atom, a substituted or unsubstituted silyl group, a substituted or unsubstituted alkyl group of 1 to 20 carbon atoms, a substituted or unsubstituted aryl group of 6 to 30 carbon atoms for forming a ring, or a substituted or unsubstituted heteroaryl group of 2 to 30 carbon atoms for forming a ring, or may be combined with an adjacent group to form a ring. m1 and m2 are each independently an integer of 0 to 4, and m3 and m4 are each independently an integer of 0 to 5.

In case where m1 is 1, W₁ may not be a hydrogen atom, in case where m2 is 1, W₂ may not be a hydrogen atom, in case where m3 is 1, W₃ may not be a hydrogen atom, and in case where m4 is 1, W₄ may not be a hydrogen atom.

In case where m1 is 2 or more, a plurality of W₁ groups are the same or different. In case where m2 is 2 or more, a plurality of W₂ groups are the same or different. In case where m3 is 2 or more, a plurality of W₃ groups are the same or different. In case where m4 is 2 or more, a plurality of W₄ groups are the same or different.

The compound represented by Formula 5 may include, for example, the compounds represented by the structures below. However, an embodiment of the compound represented by Formula 5 is not limited thereto.

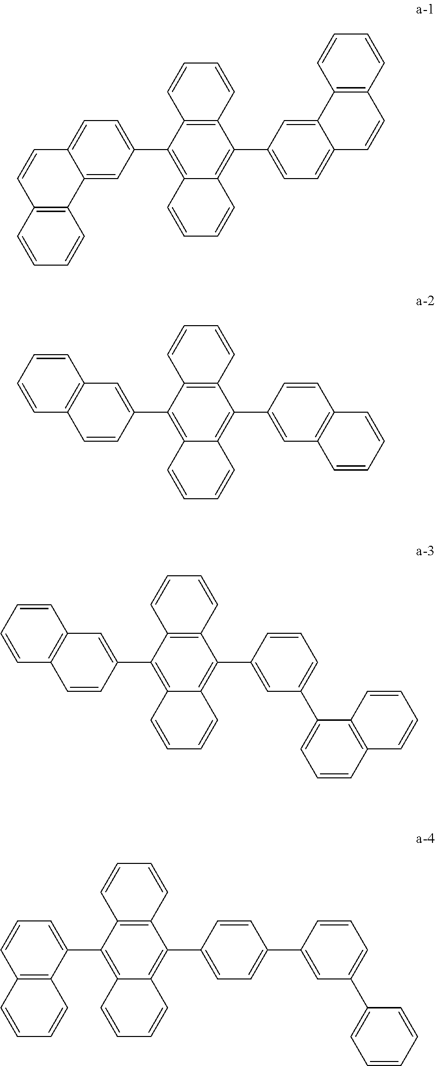

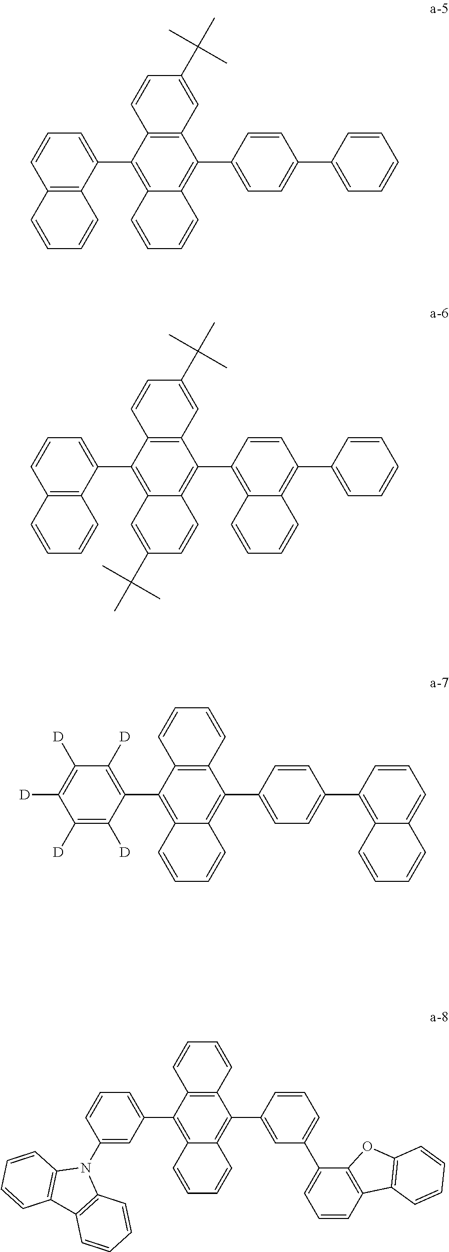

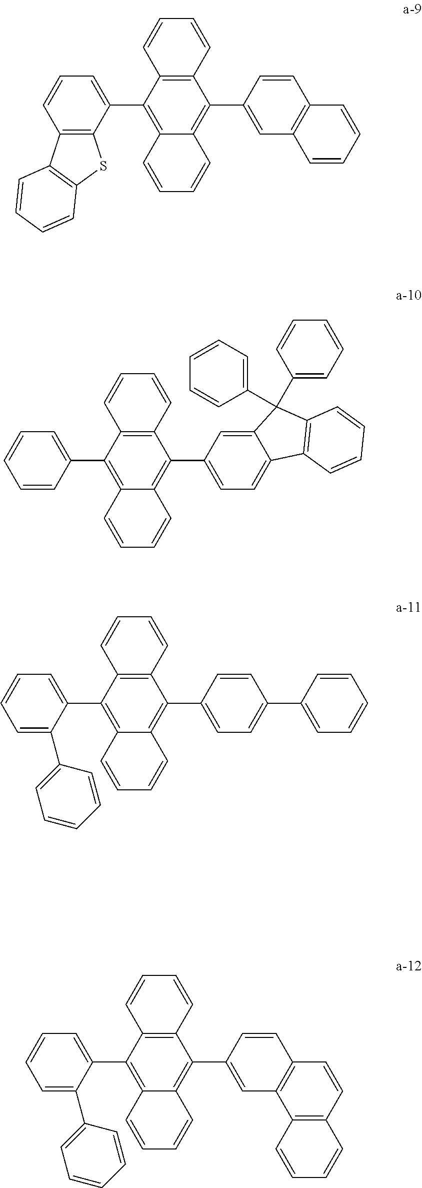

In an embodiment, the emission layer EML may include as a host material, tris(8-hydroxyquinolino)aluminum (Alq₃), 4,4′-bis(N-carbazolyl)-1,1′-biphenyl (CBP), poly(N-vinylcarbazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2″-dimethyl-biphenyl(CDBP), 2-methyl-9,10-bis(naphthalen-2-yl)anthracene (MADN), bis[2-(diphenylphosphino)phenyl]ether oxide (DPEPO), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), 2,8-bis(diphenylphosphoryl)dibenzofuran (PPF), 3,3′-bis(N-carbazolyl)-1,1′-biphenyl (mCBP), 1,3-bis(N-carbazolyl)benzene (mCP), 9,10-di(naphthalen-2-yl)anthracene (DNA), and/or the like. However, an embodiment of the present disclosure is not limited thereto. Any suitable host materials available in the art for emitting delayed fluorescence other than the suggested host materials may be included.

In the organic electroluminescence device 10 of an embodiment, the emission layer EML may further include any suitable dopant material available in the art. In an embodiment, the emission layer EML may include as a dopant, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), perylene and the derivatives thereof (for example, 2,5,8,11-tetra-t-butylperylene (TBP)), pyrene and the derivatives thereof (for example, 1,1-dipyrene, 1,4-dipyrenylbenzene, 1,4-bis(N,N-diphenylamino)pyrene), and/or the like.

In addition, in an embodiment, the emission layer EML may include two dopant materials having different lowest triplet excitation energy levels (T1 levels) from each other. In the organic electroluminescence device 10 of an embodiment, the emission layer EML may include a host having the first lowest triplet excitation energy level, a first dopant having the second lowest triplet excitation energy level which is lower than the first lowest triplet excitation energy level, and a second dopant having the third lowest triplet excitation energy level which is lower than the second lowest triplet excitation energy level. In an embodiment, the emission layer EML may include the above-described fused polycyclic compound as the first dopant.

In the organic electroluminescence device 10 of an embodiment, including the host, the first dopant and the second dopant in the emission layer EML, the first dopant may be a delayed fluorescence dopant, and the second dopant may be a fluorescence dopant. In addition, in the organic electroluminescence device 10 of an embodiment, the fused polycyclic compound represented by Formula 1 may play the role of an assistant dopant.

For example, in case where the emission layer EML of the organic electroluminescence device 10 of an embodiment includes a plurality of dopants, the emission layer EML may include the fused polycyclic compound of an embodiment as the first dopant, and the above-described dopant material as the second dopant. For example, in case where the emission layer EML emits blue light, the emission layer EML may further include as the second dopant, any one selected from the group consisting of styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), perylene and the derivatives thereof (for example, 2,5,8,11-tetra-t-butylperylene (TBP)), pyrene and the derivatives thereof (for example, 1,1-dipyrene, 1,4-dipyrenylbenzene, 1,4-bis(N,N-diphenylamino)pyrene), and the like. In addition, a metal complex or an organometallic complex, including Ir, Pt, Pd, etc. as a core atom such as (4,6-F₂ppy)₂Irpic, may be used as the second dopant.

In the organic electroluminescence device 10 of an embodiment, including the fused polycyclic compound of an embodiment as the first dopant of the emission layer EML, the emission layer EML may emit green light or red light, and in this case, the second dopant material used may be the above-described dopant, any suitable green fluorescence dopant available in the art, and/or any suitable red fluorescence dopant available in the art.

In the organic electroluminescence device 10 of an embodiment, the emission layer EML may be a phosphorescence emission layer. For example, the fused polycyclic compound according to an embodiment may be included in the emission layer EML as a phosphorescence host material.

In the organic electroluminescence device 10 of an embodiment, as shown in FIGS. 1 to 4, the electron transport region ETR is on the emission layer EML. The electron transport region ETR may include at least one selected from an electron blocking layer HBL, an electron transport layer ETL, and an electron injection layer EIL. However, an embodiment of the present disclosure is not limited thereto.

The electron transport region ETR may have a single layer formed using a single material, a single layer formed using a plurality of different materials, or a multilayer structure having a plurality of layers formed using a plurality of different materials.

For example, the electron transport region ETR may have a single layer structure of an electron injection layer EIL or an electron transport layer ETL, or a single layer structure formed using an electron injection material and an electron transport material. Further, the electron transport region ETR may have a single layer structure having a plurality of different materials, or a structure laminated from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

If the electron transport region ETR includes an electron transport layer ETL, the electron transport region ETR may include an anthracene-based compound. The electron transport region may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1, 10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq2), 9,10-di(naphthalene-2-yl)anthracene (ADN), diphenyl(4-(triphenylsilyl)phenyl)phosphine oxide (TSPO1), or a mixture thereof, without limitation. The thickness of the electron transport layer ETL may be from about 100 Å to about 1,000 Å and may be, for example, from about 150 Å to about 500 Å. If the thickness of the electron transport layer ETL satisfies the above-described range, suitable or satisfactory electron transport properties may be obtained without substantial increase of a driving voltage.

If the electron transport region ETR includes the electron injection layer EIL, the electron transport region ETR may include, a metal halide such as LiF, NaCl, CsF, RbCl, Rbl, and Cul, a metal in lanthanides such as Yb, a metal oxide such as Li₂O and BaO, and/or lithium quinolate (LiQ). However, an embodiment of the present disclosure is not limited thereto. The electron injection layer EIL also may be formed using a mixture material of an electron transport material and an insulating organo metal salt. The organo metal salt may be a material having an energy band gap of about 4 eV or more. For example, the organo metal salt may include metal acetates, metal benzoates, metal acetoacetates, metal acetylacetonates, and/or metal stearates. The thickness of the electron injection layer EIL may be from about 1 Å to about 500 Å, and from about 3 Å to about 300 Å. If the thickness of the electron injection layer EIL satisfies the above-described range, suitable or satisfactory electron injection properties may be obtained without inducing substantial increase of a driving voltage.

The electron transport region ETR may include a hole blocking layer HBL as described herein above. The hole blocking layer HBL may include, for example, at least one selected from 2,9-dimethyl-4,7-diphenyl-1, 10-phenanthroline (BCP), or 4,7-diphenyl-1, 10-phenanthroline (Bphen). However, an embodiment of the present disclosure is not limited thereto.

The second electrode EL2 is provided on the electron transport region ETR. The second electrode EL2 may be a common electrode or a cathode. The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, and/or the like.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). The second electrode EL2 may have a multilayered structure including a reflective layer or a transflective layer formed using the above-described materials and a transparent conductive layer formed using ITO, IZO, ZnO, ITZO, and/or the like.

In some embodiments, the second electrode EL2 may be connected with an auxiliary electrode. If the second electrode EL2 is connected with the auxiliary electrode, the resistance of the second electrode EL2 may decrease.

A capping layer (CPL) may be on the second electrode EL2 of the organic electroluminescence device 10 of an embodiment. The capping layer (CPL) may include, for example, α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), N,N′-bis(naphthalene-1-yl), and/or the like.

The organic electroluminescence device 10 according to an embodiment of the present disclosure includes the fused polycyclic compound of an embodiment in the emission layer EML between the first electrode EL1 and the second electrode EL2, thereby showing high emission efficiency properties. In addition, the fused polycyclic compound according to an embodiment may be a thermally activated delayed fluorescence dopant, and the emission layer EML may include the fused polycyclic compound of an embodiment to emit thermally activated delayed fluorescence. Accordingly, high emission efficiency properties may be achieved.

The fused polycyclic compound of an embodiment may be included in an organic layer other than the emission layer EML as a material for the organic electroluminescence device 10. For example, the organic electroluminescence device 10 according to an embodiment of the present disclosure may include the fused polycyclic compound in at least one organic layer between the first electrode EL1 and the second electrode EL2, or in the capping layer (CPL) on the second electrode EL2.

The fused polycyclic compound of an embodiment includes Al, Ga, or In as a ring-forming central atom which forms fused rings, and may relatively decrease a difference (AEST) between the lowest triplet excitation energy level (T1 level) and the lowest singlet excitation energy level (S1 level) when compared with the existing polycyclic compound including B as the ring-forming central atom. Accordingly, if used as a material for an organic electroluminescence device, the efficiency of the organic electroluminescence device may be further improved.

Hereinafter, the fused polycyclic compound according to an embodiment and the organic electroluminescence device of an embodiment of the present disclosure will be explained in more detail with reference to example embodiments and comparative embodiments. The following embodiments are only illustrations to assist the understanding of the subject matter of the present disclosure, and the scope of the present disclosure is not limited thereto.

### Examples

### 1. Synthesis of Fused Polycyclic Compounds

First, the synthetic method of the fused polycyclic compounds according to exemplary embodiments will be explained in more detail with reference to the synthetic methods of Compound 1, Compound 4, Compound 22, and Compound 25. In addition, the synthetic methods of the fused polycyclic compounds explained herein below are only embodiments, and the synthetic method of the fused polycyclic compound according to an embodiment of the present disclosure is not limited thereto.

### (1) Synthesis of Compound 1

Fused Polycyclic Compound 1 according to an embodiment may be synthesized, for example, according to Reaction 1 below.

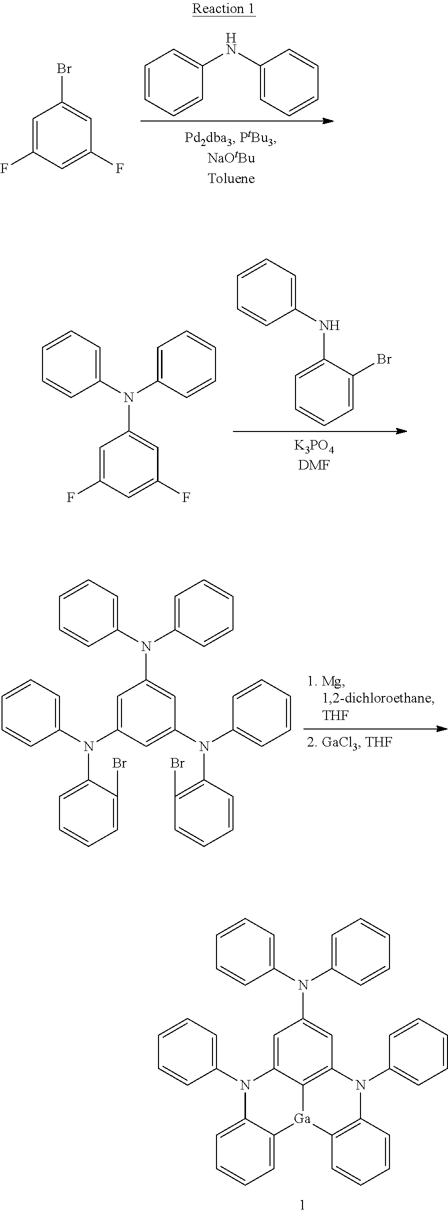

7.38 g (10 mmol) of N1,N3-bis(2-bromophenyl)-N1,N3,N5,N5-tetraphenylbenzene-1,3,5-triamine, and 2.4 g (100 mmol) of Mg were dissolved in 60 m1 of THF, and three drops of 1,2-dichloroethane were added to initiate the reaction. Stirring was performed at room temperature for about 1 hour, and 5.28 g (30 mmol) of GaCl₃ was added. According to Reaction 1, 0.12 g (yield 2%) of a compound was synthesized. From confirmation results through MS/FAB and ¹H NMR, the product thus produced had a molecular structure of C₄₂H₃₀GaN₃ and a molecular weight of 645.19. From the results, the compound thus obtained was identified as Compound 1.

### (2) Synthesis of Compound 4

Fused Polycyclic Compound 4 according to an embodiment may be synthesized, for example, by Reaction 2 below.

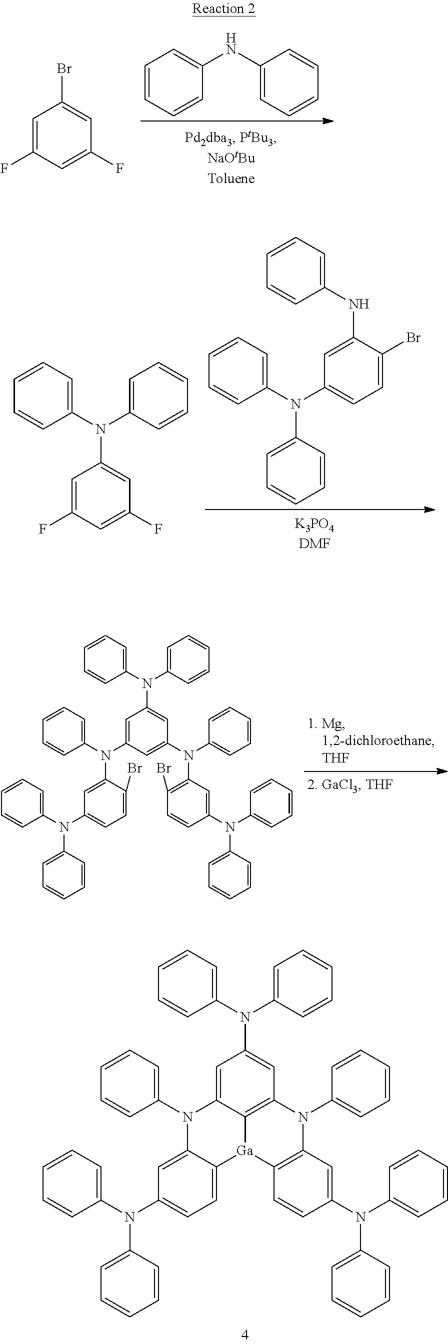

Fused Polycyclic Compound 4 was prepared using 4-bromo-N1,N1,N3-triphenylbenzene-1,3-diamine instead of 2-bromo-N-phenylaniline of Reaction 1.

0.19 g (yield 2%) of Compound 4 was synthesized by conducting substantially the same method as the synthetic method of Compound 1, by using 9.14 g (10 mmol) of 3,5-diphenoxy-N,N-diphenylaniline. From confirmation results through MS/FAB and ¹H NMR, the product thus produced had a molecular structure of C₆₆H₄₈GaN₅ and a molecular weight of 979.33. From the results, the compound thus obtained was identified as Compound 4.

### (3) Synthesis of Compound 22

Fused Polycyclic Compound 22 according to an embodiment may be synthesized, for example, by Reaction 3 below.

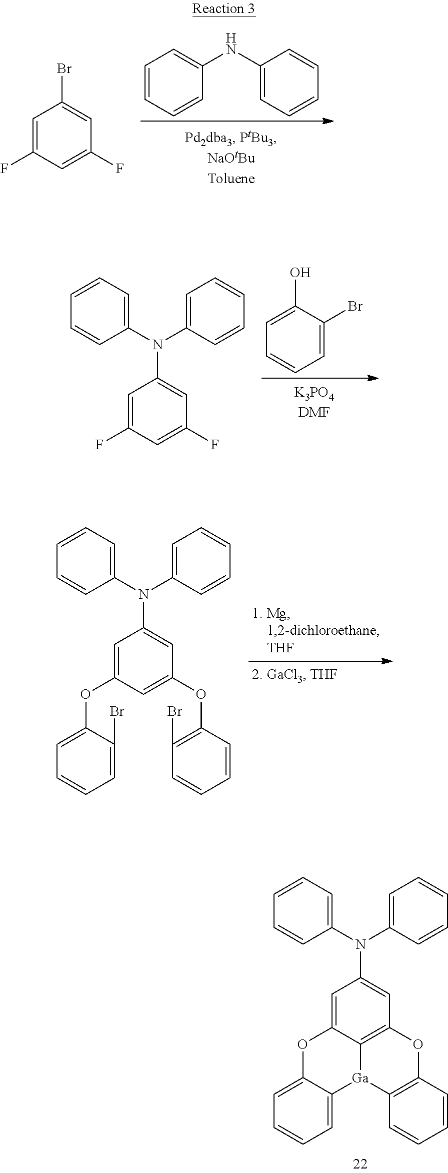

Fused Polycyclic Compound 22 was prepared using 2-bromophenol instead of 2-bromo-N-phenylaniline of Reaction 1.

0.13 g (yield 2%) of Compound 22 was synthesized by conducting substantially the same method as the synthetic method of Compound 1, by using 6.44 g (15 mmol) of 3,5-diphenoxy-N,N-diphenylaniline. From confirmation results through MS/FAB and ¹H NMR, the product thus produced had a molecular structure of C₃₀H₂₀GaNO₂ and a molecular weight of 495.03. From the results, the compound thus obtained was identified as Compound 22.

### (4) Synthesis of Compound 25

Fused Polycyclic Compound 25 according to an embodiment may be synthesized, for example, by Reaction 4 below.

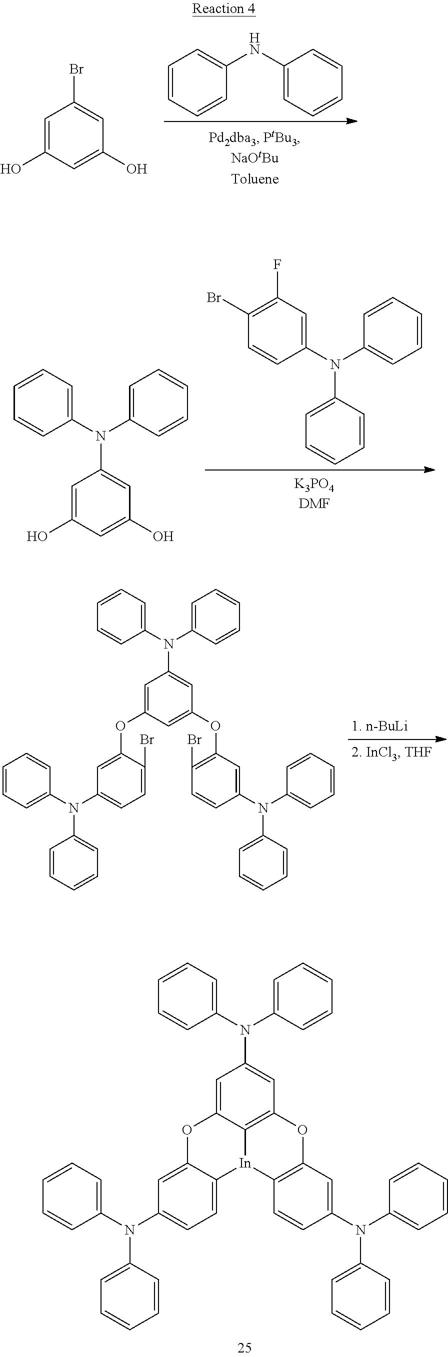

0.16 g (yield 2%) of Fused Polycyclic Compound 25 was prepared by Reaction 4 using 9.19 g (10 mmol) of 3,3′-((5-(diphenylamino)-1,3-phenylene)bis(oxy))bis(4-bromo-N,N-diphenylaniline), 16 ml (40 mmol) of 2.5 M n-BuLi, and 6.65 g (30 mmol) of InCl₃. From confirmation results through MS/FAB and ¹H NMR, the product thus produced had a molecular structure of C₅₄H₃₈N₃O₂ and a molecular weight of 875.23. From the results, the compound thus obtained was identified as Compound 25.

### 2. Evaluation of Energy Level of Fused Polycyclic Compound

The compounds used in Example 1 to Example 4 and Comparative Example 1 to Comparative Example 3 are shown in Table 1.

TABLE 1

| | | | |
|---|---|---|---|
| Compound 1 | 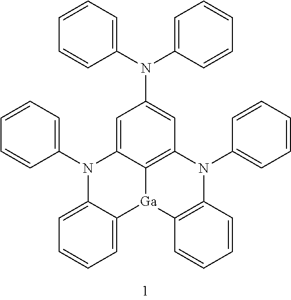 | Comparative Compound C1 | 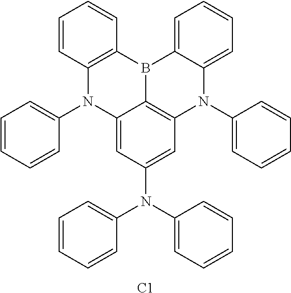 |
| Compound 4 | 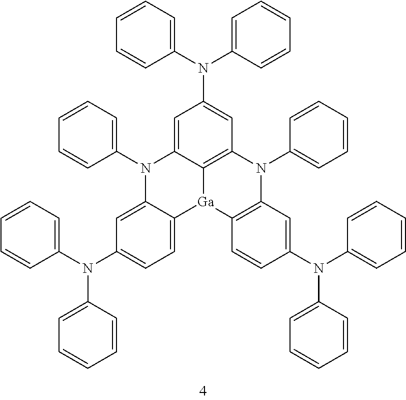 | Comparative Compound C2 | 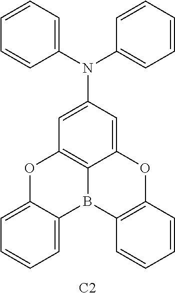 |
| Compound 22 | 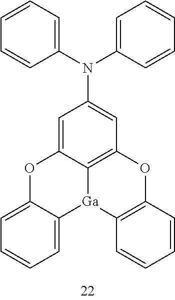 | Comparative Compound C3 | 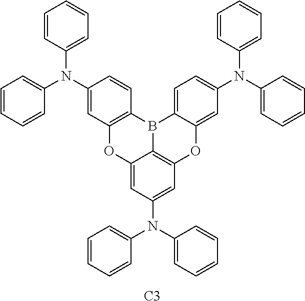 |
| Compound 25 | 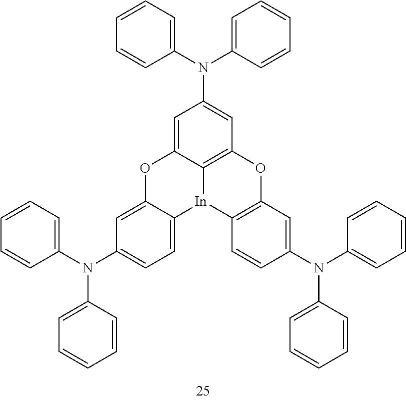 | | |

In Table 2 below, the lowest singlet excitation energy level (S1 level), the lowest triplet excitation energy level (T1 level), and EST of Compound 1, Compound 4, Compound 22, and Compound 25, which are the Example Compounds, Comparative Compound C1, Comparative Compound C2 and Comparative Compound C3 are shown. The energy level values in Table 2 were calculated by a non empirical molecular orbital method. Particularly, the calculation was performed by the Gaussian 09 software program of Gaussian Co., using density functional theory (DFT) at a B3LYP/6-30 G(d) level (e.g., was performed using the B3LYP hybrid functional and 6-31G(d) basis set). EST represents a difference between the lowest singlet excitation energy level (S1 level) and the lowest triplet excitation energy level (T1 level).

TABLE 2

| | | S1 level | T1 level | E_{ST} |
|---|---|---|---|---|
| Division | Compound type | (eV) | (eV) | (eV) |
| Example 1 | Compound 1 | 3.25 | 2.92 | 0.33 |
| Example 2 | Compound 4 | 3.17 | 2.86 | 0.31 |
| Example 3 | Compound 22 | 3.23 | 2.91 | 0.32 |
| Example 4 | Compound 25 | 3.19 | 2.87 | 0.32 |
| Comparative | Comparative | 3.14 | 2.67 | 0.49 |
| Example 1 | Compound C1 | | | |
| Comparative | Comparative | 3.17 | 2.76 | 0.41 |
| Example 2 | Compound C2 | | | |
| Comparative | Comparative | 2.99 | 2.62 | 0.37 |
| Example 3 | Compound C3 | | | |

It could be confirmed that Compound 1, Compound 4, Compound 22, and Compound 25, which are the Example Compounds, showed smaller EST values when compared with Comparative Compound C1, Comparative Compound C2 and Comparative Compound C3. Because Compound 1, Compound 4, Compound 22, and Compound 25, which are the Example Compounds showed small EST values of about 3.3 eV or less, these compounds could be used as dopant materials for thermally activated delayed fluorescence, with high light efficiency.

### 3. Manufacture and Evaluation of Organic Electroluminescence Device Including Fused Polycyclic Compound

Manufacture of Organic Electroluminescence Device

An organic electroluminescence device of an embodiment including the fused polycyclic compound of an embodiment in an emission layer was manufactured by a method described herein below. Organic electroluminescence devices of Examples 1 to 4 were manufactured using the fused polycyclic compounds of Compound 1, Compound 4, Compound 22, and Compound 25 as dopant materials for an emission layer. The organic electroluminescence device of Comparative Example 1 to Comparative Example 3 were manufactured using Comparative Compound C1 to Comparative Compound C3 as dopant materials in an emission layer.

On a glass substrate, ITO with a thickness of about 1,200 Å was patterned and washed with isopropyl alcohol and ultra-pure water, washed with ultrasonic waves for about 5 minutes, exposed to UV for about 30 minutes and treated with ozone. Then, NPD was vacuum deposited to a thickness of about 300 Å to form a hole injection layer, and TCTA was deposited to a thickness of about 200 Å and CzSi was vacuum deposited to a thickness of about 100 Å to form a hole transport layer.

On the hole transport layer, mCP and the fused polycyclic compound of an embodiment of the present disclosure or Comparative Compound were co-deposited to a ratio of 99:1 to form an emission layer with a thickness of about 200 Å. The emission layer formed by the co-deposition, was formed by mixing Compound 1, Compound 4, Compound 22, or Compound 25 with mCP and depositing in Example 1 to Example 4, respectively, or by mixing a respective one of Comparative Compound C1 to Comparative Compound C3 with mCP and depositing in Comparative Example 1 to Comparative Compound 3.

On the emission layer, an electron transport layer was formed using TPSO1 to a thickness of about 200 Å, and then, an electron injection layer was formed by depositing TPBi to a thickness of about 300 Å and LiF to a thickness of about 10 Å in order. Then, a second electrode was formed using aluminum (Al) to a thickness of about 3,000 Å on the electron injection layer.

Compounds used in the Examples and Comparative Examples are shown below.

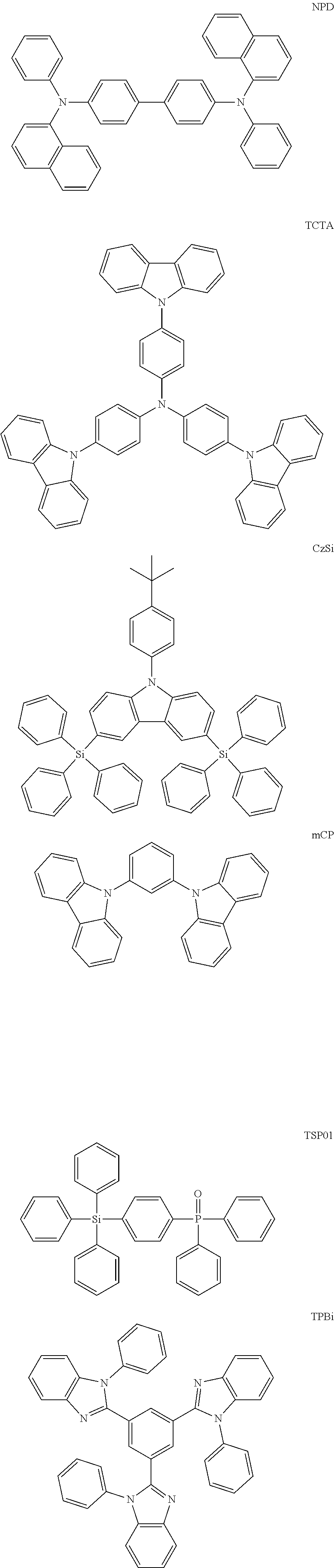 [SMILES: c1ccc(N(c2ccc(-c3ccc(N(c4ccccc4)c4cccc5ccccc45)cc3)cc2)c2cccc3ccccc23)cc1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; c1cc(-n2c3ccccc3c3ccccc32)cc(-n2c3ccccc3c3ccccc32)c1 ; O=P(c1ccccc1)(c1ccccc1)c1ccc([Si](c2ccccc2)(c2ccccc2)c2ccccc2)cc1 ; c1ccc(-n2c(-c3cc(-c4nc5ccccc5n4-c4ccccc4)cc(-c4nc5ccccc5n4-c4ccccc4)c3)nc3ccccc32)cc1]

### Evaluation of Properties of Organic Electroluminescence Device

In Table 3, the evaluation results on the organic electroluminescence devices of Example 1 to Example 4 and Comparative Example 1 to Comparative Example 3 are shown. In Table 3, the driving voltage, emission efficiency and external quantum efficiency (EQE) of the organic electroluminescence devices thus manufactured are compared and shown.

In the evaluation results of the properties on the Examples and the Comparative Example, as shown in Table 3, a voltage and current density were measured using a source meter (Keithley Instrument Co., 2400 series), and the external quantum efficiency (EQE) was measured using an external quantum efficiency measurement apparatus C9920-12 of HAMAMATSU Photonics Co. The emission efficiency represents a current efficiency value with respect to current density of 10 mA/cm².

TABLE 3

| Device | Dopant | Driving | Emission | | Color of |
|---|---|---|---|---|---|
| manufacturing | material of | voltage | efficiency | EQE | emitted |
| example | emission layer | (V) | (cd/A) | (%) | light |
| Example 1 | Compound 1 | 5.5 | 16.8 | 18.9 | Blue |
| Example 2 | Compound 4 | 5.1 | 23.2 | 22.1 | Blue |
| Example 3 | Compound 22 | 5.4 | 21.8 | 20.3 | Blue |
| Example 4 | Compound 25 | 5.6 | 22.7 | 21.6 | Blue |
| Comparative | Comparative | 5.7 | 15.4 | 14.5 | Blue |
| Example 1 | Compound C1 | | | | |
| Comparative | Comparative | 5.9 | 14.2 | 13.1 | Blue |
| Example 2 | Compound C2 | | | | |
| Comparative | Comparative | 6.2 | 15.7 | 14.9 | Blue |
| Example 3 | Compound C3 | | | | |

Referring to the results in Table 3, the organic electroluminescence devices according to the Examples using the fused polycyclic compound according to an embodiment of the present disclosure as a material for an emission layer, were found to show similar driving voltage values and relatively higher emission efficiency and external quantum efficiency when compared with the Comparative Examples. In the case of the Example Compounds, TADF properties are shown by using multiple resonance phenomenon by aromatic rings which form fused rings, and may have small EST values by including Al, Ga, or In as a ring-forming central atom which forms the fused rings, as compared with the Comparative Compounds C1 to C3, which include B as a ring-forming central atom. Accordingly, the organic electroluminescence devices of the Examples may show improved emission efficiency as compared to the organic electroluminescence devices of the Comparative Examples. For example, the organic electroluminescence device of an embodiment may accomplish high emission efficiency in a blue light wavelength region by including the fused polycyclic compound of an embodiment as a material for an emission layer.

The organic electroluminescence device of an embodiment may show improved device characteristics showing high emission efficiency in a blue light region.

The fused polycyclic compound of an embodiment may be included in an emission layer of an organic electroluminescence device and may contribute to increasing the efficiency of the organic electroluminescence device.

Although exemplary embodiments of the present disclosure have been described, it is understood that the present disclosure should not be limited to these exemplary embodiments but various changes and modifications can be made by one ordinary skilled in the art within the spirit and scope of the present disclosure as hereinafter claimed.

What is claimed is:

1. An organic electroluminescence device, comprising:
a first electrode;
a second electrode facing the first electrode; and
a plurality of organic layers between the first electrode and the second electrode,
wherein the first electrode and the second electrode each independently comprise at least one selected from Ag, Mg, Cu, Al, Pt, Pd, Au, Ni, Nd, Ir, Cr, Li, Ca, LiF/Ca, LiF/Al, Mo, Ti, In, Sn, Zn, a compound of two or more thereof, a mixture of two or more thereof, and oxides of one or more thereof,
wherein at least one organic layer among the organic layers comprises a fused polycyclic compound represented by the following Formula 1: 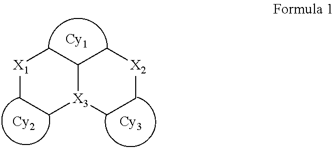
in Formula 1,
M is Al, Ga, or In,
X₁ and X₂ are each independently NR₁, O, S, P(═O)R₂, or P(═S)R₃,
R₁ to R₃ are each independently a hydrogen atom, a deuterium atom, a halogen atom, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring, and
Cy₁ to Cy₃ are each independently a substituted or unsubstituted aromatic hydrocarbon ring, a substituted or unsubstituted aromatic heterocycle, or combined with an adjacent group to form a ring.

2. The organic electroluminescence device of claim 1, wherein,
the plurality of organic layers comprise:
a hole transport region on the first electrode;
an emission layer on the hole transport region; and
an electron transport region on the emission layer, and
the emission layer comprises the fused polycyclic compound represented by Formula 1.

3. The organic electroluminescence device of claim 2, wherein the emission layer emits delayed fluorescence.

4. The organic electroluminescence device of claim 2, wherein,
the emission layer is a delayed fluorescence emission layer comprising a host and a dopant, and
the dopant comprises the fused polycyclic compound represented by Formula 1.

5. The organic electroluminescence device of claim 2, wherein,
the emission layer comprises:
a host having a first lowest triplet excitation energy level;
a first dopant having a second lowest triplet excitation energy level which is lower than the first lowest triplet excitation energy level; and
a second dopant having a third lowest triplet excitation energy level which is lower than the second lowest triplet excitation energy level, and
the first dopant comprises the fused polycyclic compound represented by Formula 1.

6. The organic electroluminescence device of claim 5, wherein,
the first dopant is a delayed fluorescence dopant, and
the second dopant is a fluorescence dopant.

7. The organic electroluminescence device of claim 1, wherein,
the fused polycyclic compound represented by Formula 1 is represented by the following Formula 2: 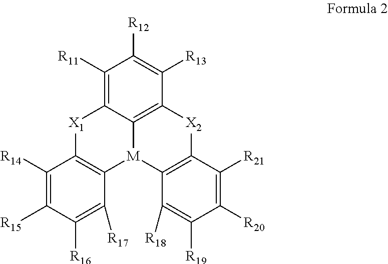
wherein, in Formula 2,
R₁₁ to R₂₁ are each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring, and
M, X₁, and X₂ are the same as defined in Formula 1.

8. The organic electroluminescence device of claim 7, wherein at least one selected from among R₁₁ to R₂₁ is a substituted or unsubstituted amine group, or a substituted or unsubstituted carbazole group.

9. The organic electroluminescence device of claim 7, wherein the fused polycyclic compound represented by Formula 2 is represented by the following Formula 3: 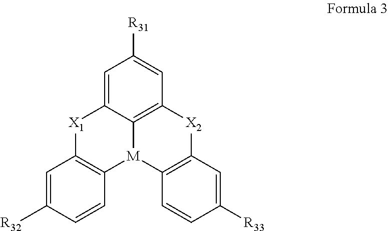
wherein, in Formula 3,
R₃₁ to R₃₃ are each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring,
at least one selected from among R₃₁ to R₃₃ is a substituted or unsubstituted amine group, or a substituted or unsubstituted carbazole group, and
M, X₁, and X₂ are the same as defined in Formula 1.

10. The organic electroluminescence device of claim 9, wherein,
at least one selected from among R₃₁ to R₃₃ is represented by the following Formula 4-1 or Formula 4-2: 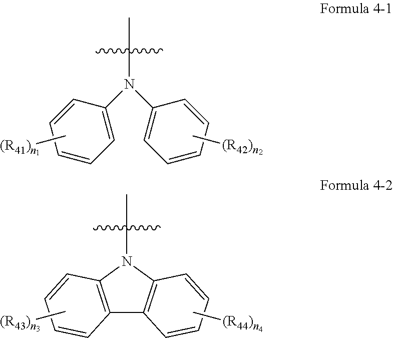
wherein, in Formulae 4-1 and 4-2,
R₄₁ to R₄₄ are each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring,
n₁ and n₂ are each independently an integer of 0 to 5, and
n₃ and n₄ are each independently an integer of 0 to 4.

11. The organic electroluminescence device of claim 1, wherein,
X₁ and X₂ are each independently NR₁, or O, and
R₁ is a substituted or unsubstituted phenyl group.

12. The organic electroluminescence device of claim 1, wherein the fused polycyclic compound represented by Formula 1 is at least one selected from among compounds in the following Compound Group 1:

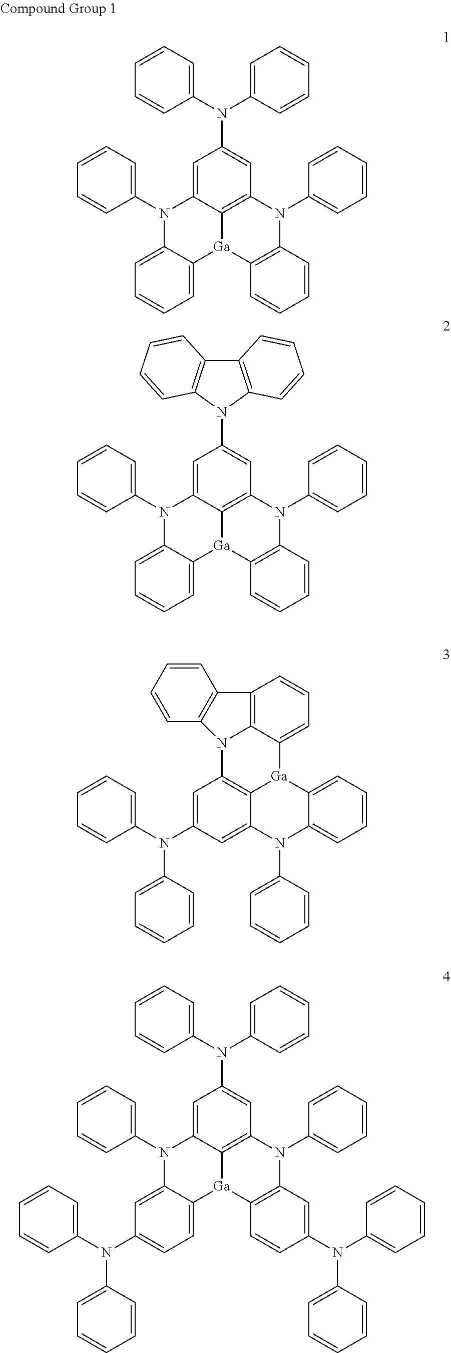

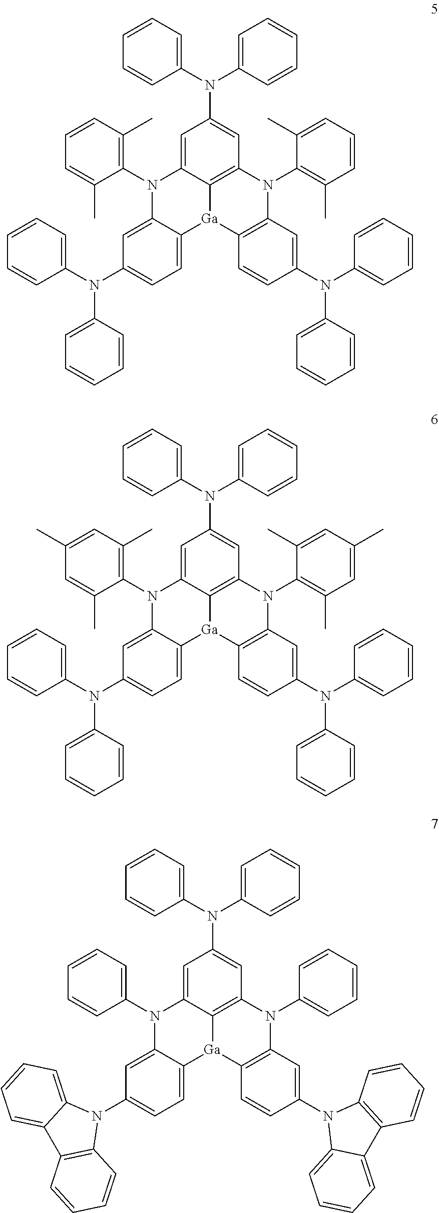

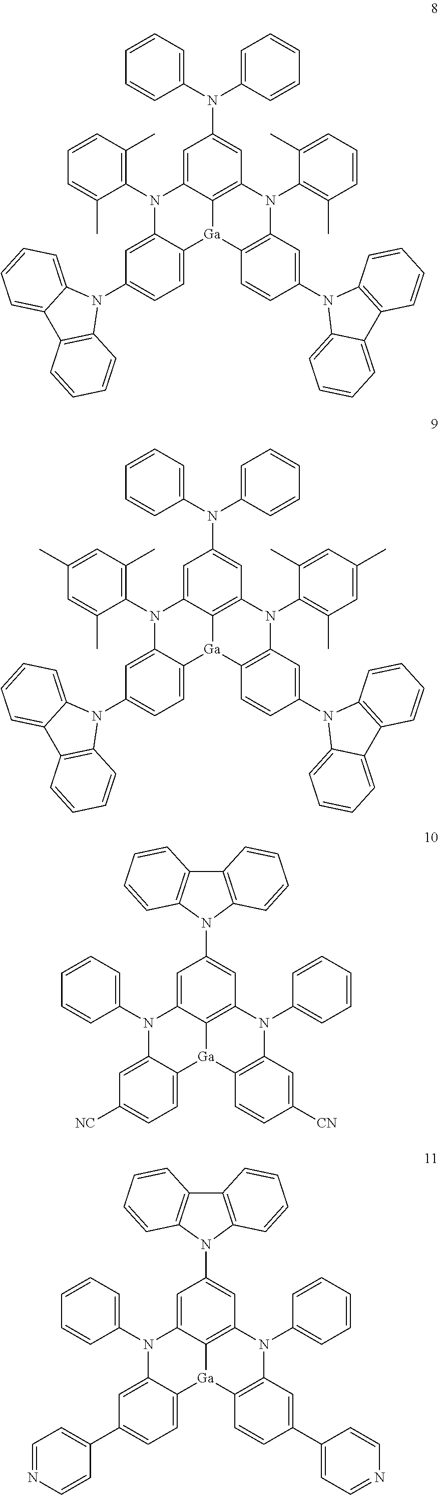

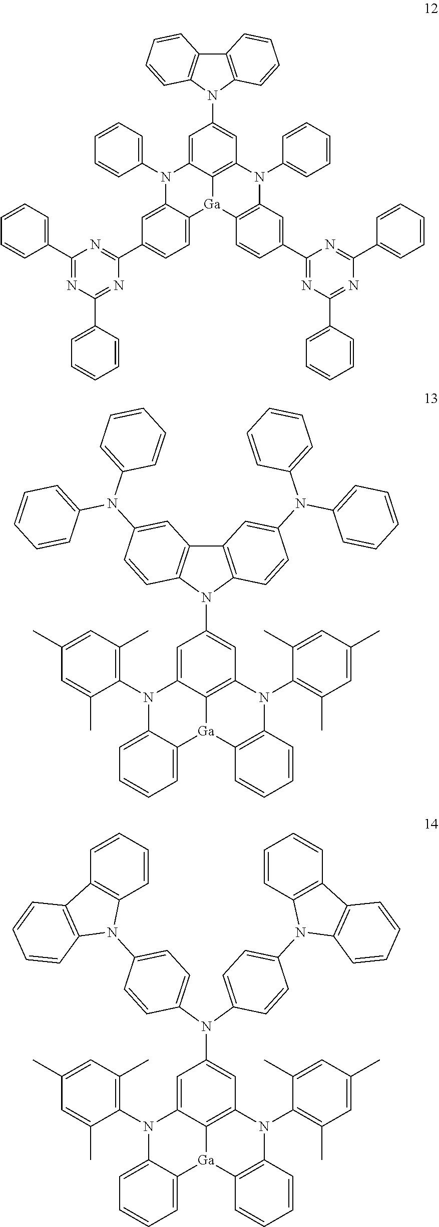

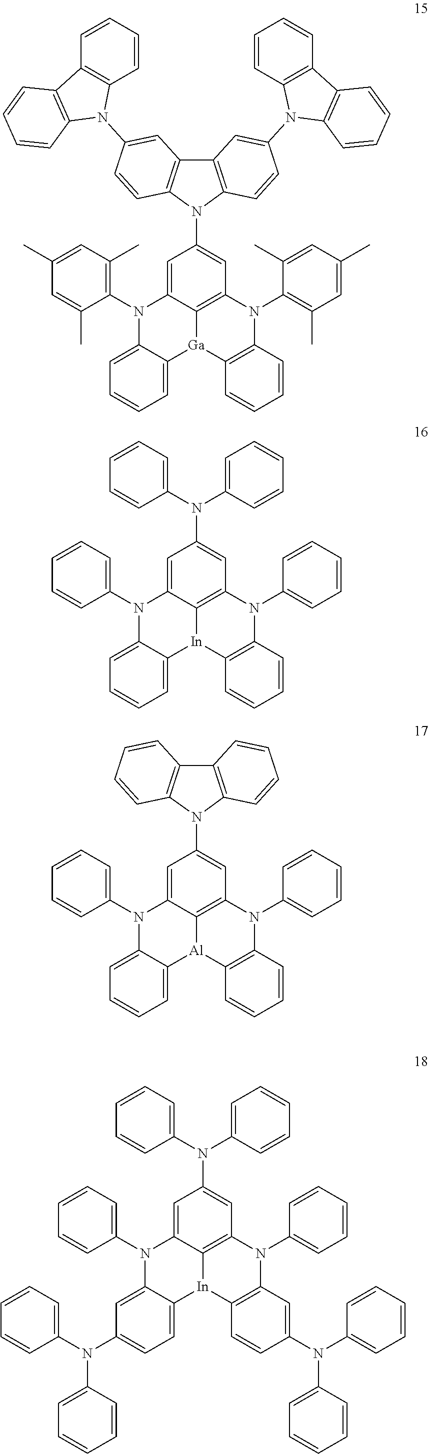

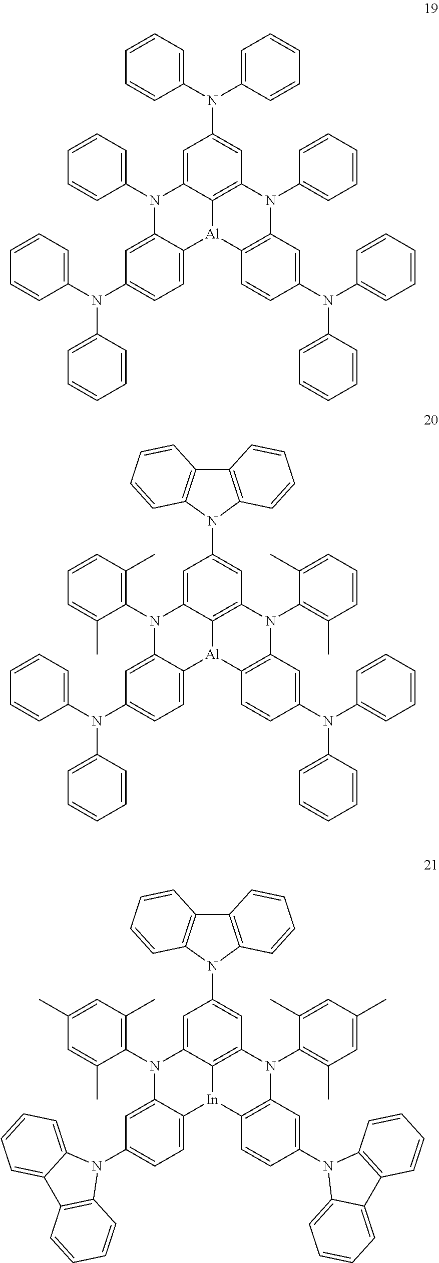

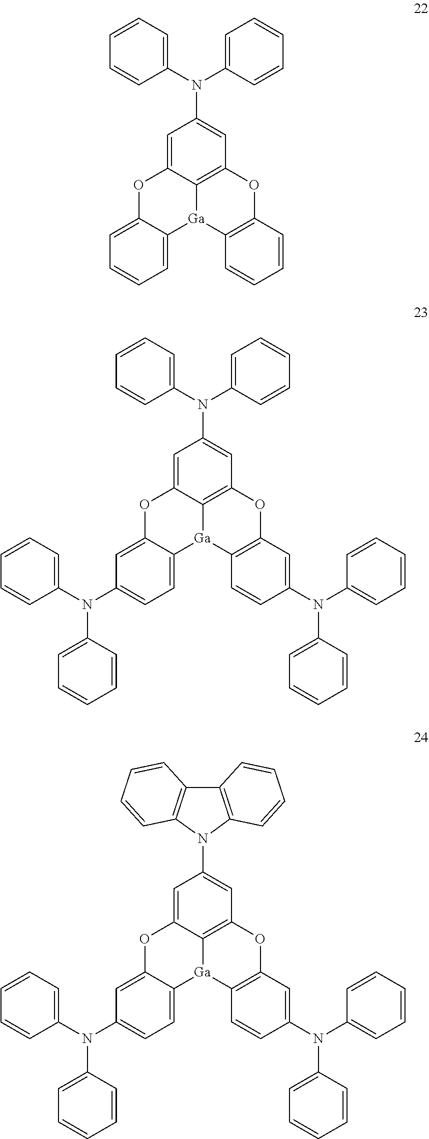

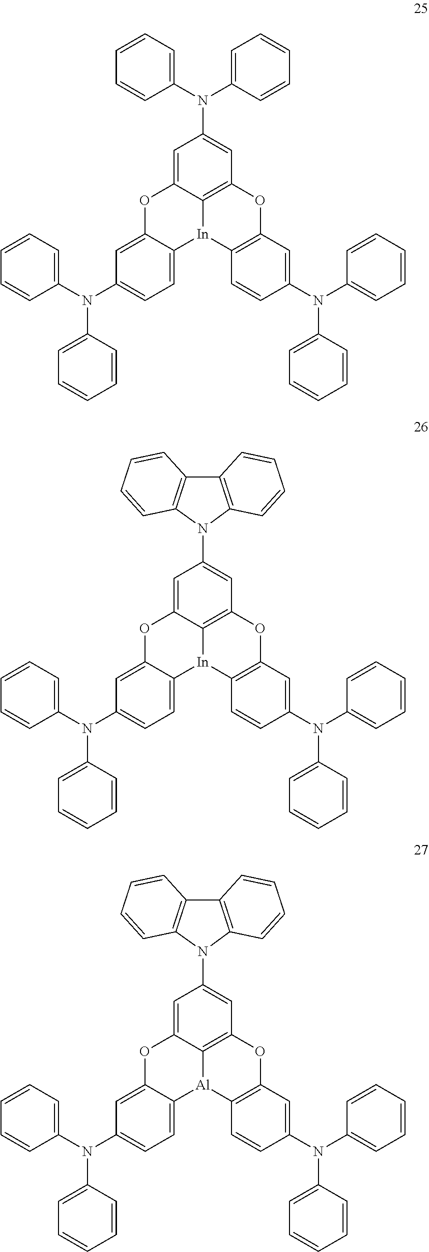

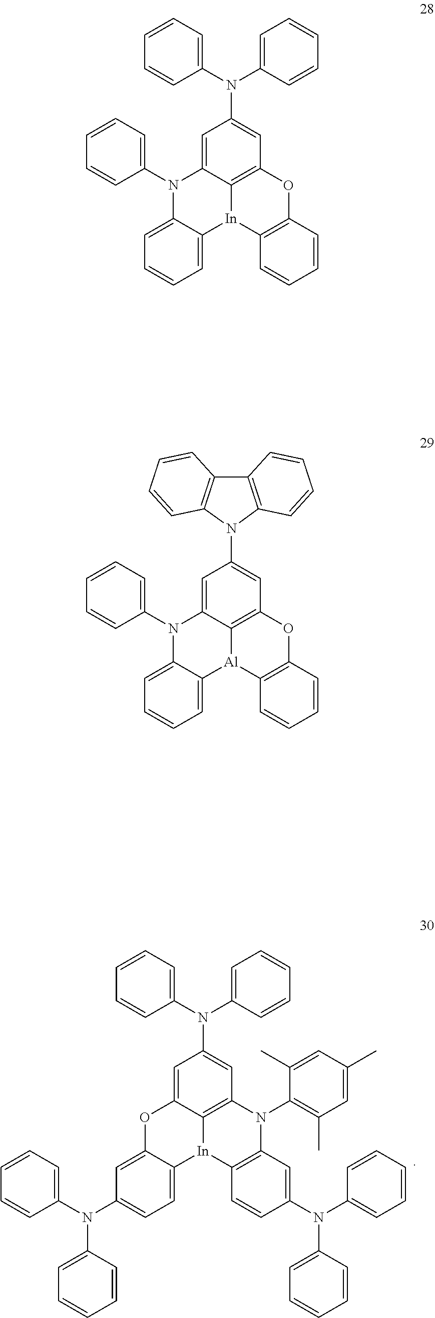

13. A fused polycyclic compound represented by the following Formula 1: 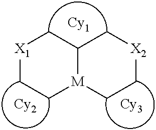
wherein, in Formula 1,
M is Al, Ga, or In,
X₁ and X₂ are each independently NR₁, O, S, P(═O)R₂, or P(═S)R₃,
R₁ to R₃ are each independently a hydrogen atom, a deuterium atom, a halogen atom, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring, and
Cy₁ to Cy₃ are each independently a substituted or unsubstituted aromatic hydrocarbon ring, or a substituted or unsubstituted aromatic heterocycle, or combined with an adjacent group to form a ring.

14. The fused polycyclic compound of claim 13, wherein,
the fused polycyclic compound represented by Formula 1 has an absolute value of a difference between a lowest singlet excitation energy level (S1) and a lowest triplet excitation energy level (T1) of about 0.33 eV or less.

15. The fused polycyclic compound of claim 13, wherein,
the fused polycyclic compound represented by Formula 1 is represented by the following Formula 2: 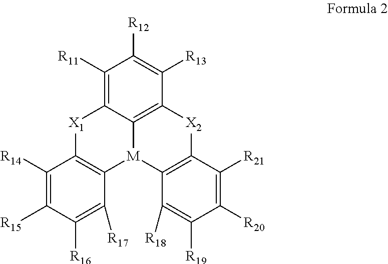
wherein, in Formula 2,
R₁₁ to R₂₁ are each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring, and
M, X₁, and X₂ are the same as defined in Formula 1.

16. The fused polycyclic compound of claim 15, wherein at least one selected from among R₁₁ to R₂₁ is a substituted or unsubstituted amine group, or a substituted or unsubstituted carbazole group.

17. The fused polycyclic compound of claim 15, wherein the compound represented by Formula 2 is represented by the following Formula 3: 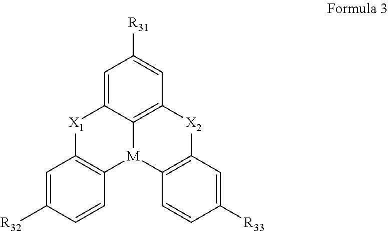
wherein, in Formula 3,
R₃₁ to R₃₃ are each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring,
at least one selected from among R₃₁ to R₃₃ is a substituted or unsubstituted amine group, or a substituted or unsubstituted carbazole group, and
M, X₁, and X₂ are the same as defined in Formula 1.

18. The fused polycyclic compound of claim 17, wherein,
at least one selected from among R₃₁ to R₃₃ is represented by the following Formula 4-1 or Formula 4-2: 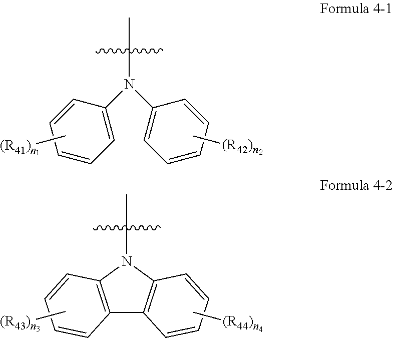
wherein, in Formulae 4-1 and 4-2,
R₄₁ to R₄₄ are each independently a hydrogen atom, a deuterium atom, a halogen atom, a substituted or unsubstituted amine group, a substituted or unsubstituted alkyl group of 1 to 20 carbon atoms, a substituted or unsubstituted aryl group of 6 to 60 carbon atoms for forming a ring, a substituted or unsubstituted heteroaryl group of 2 to 60 carbon atoms for forming a ring, or combined with an adjacent group to form a ring,
n₁ and n₂ are each independently an integer of 0 to 5, and
n₃ and n₄ are each independently an integer of 0 to 4.

19. The fused polycyclic compound of claim 13, wherein,
X₁ and X₂ are NR₁, or O, and
R₁ is a substituted or unsubstituted phenyl group.

20. The fused polycyclic compound of claim 13, wherein the fused polycyclic compound represented by Formula 1 is at least one selected from among compounds represented in the following Compound Group 1: 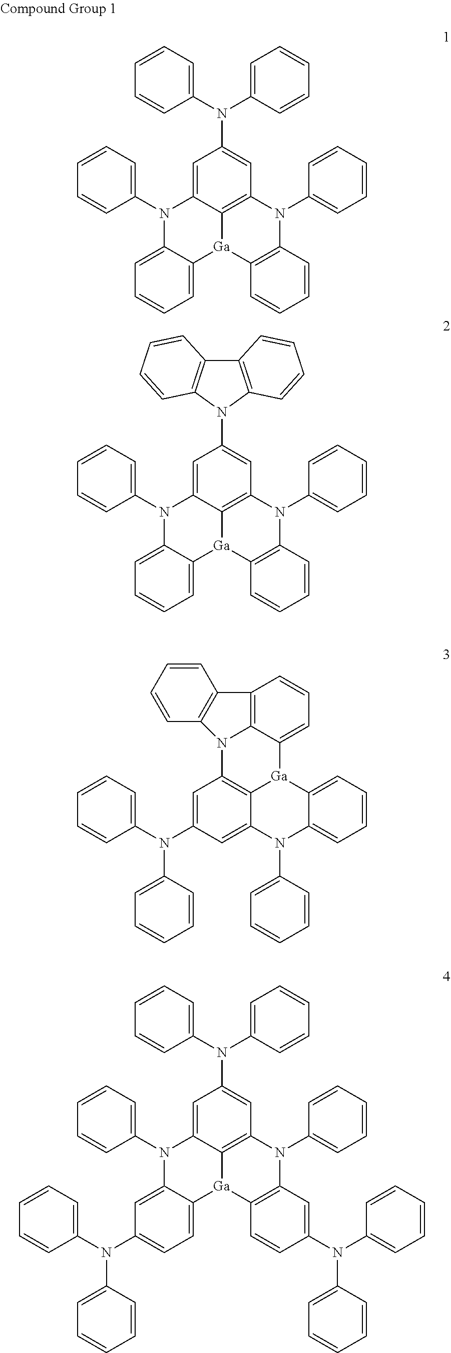 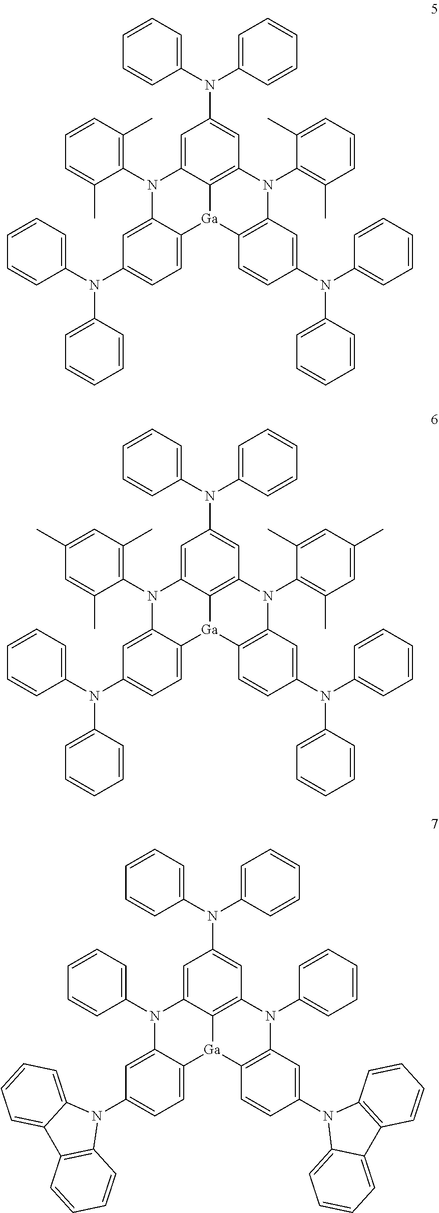 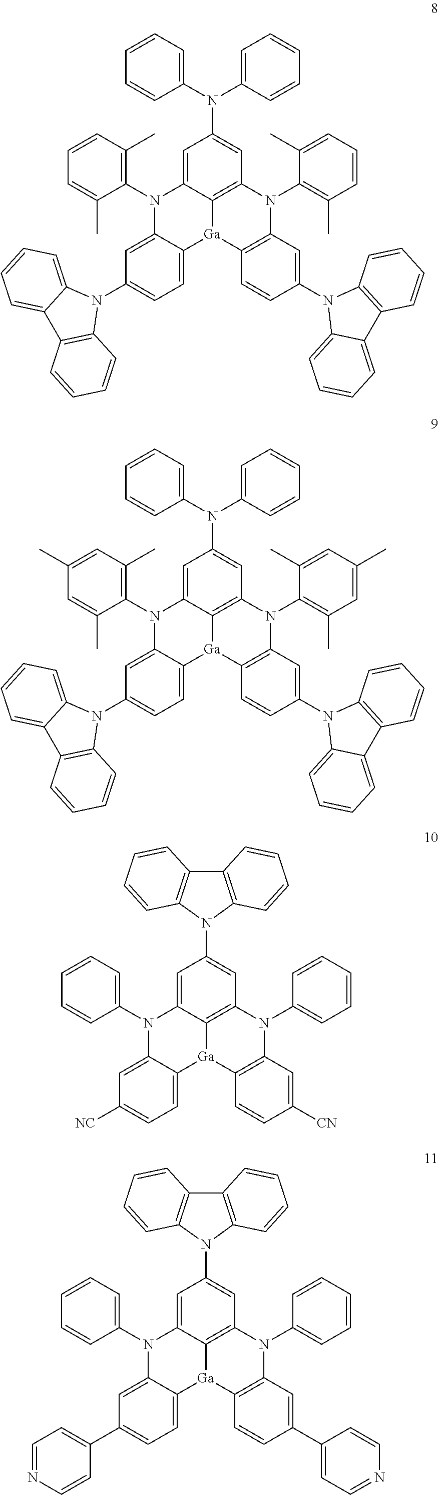 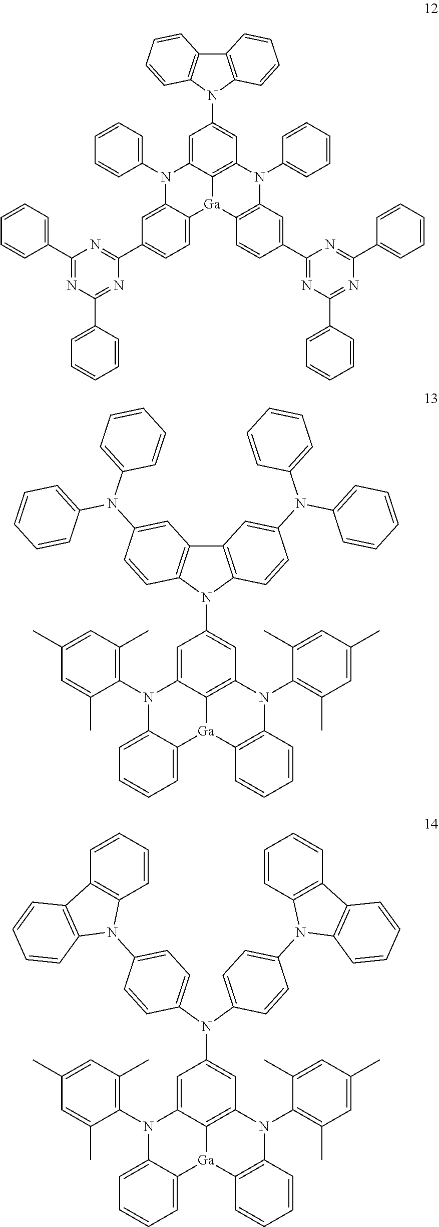 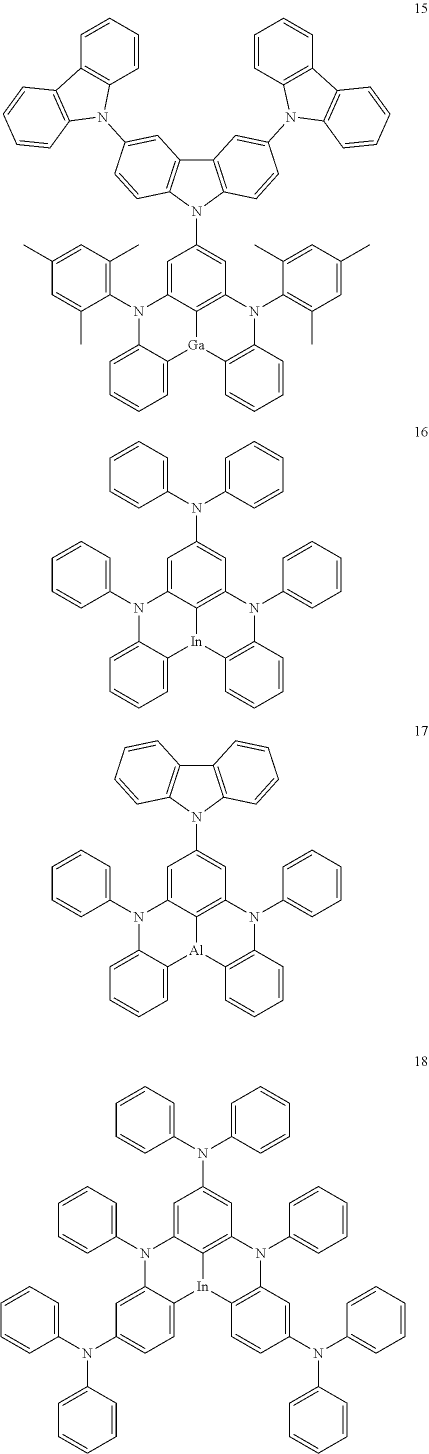 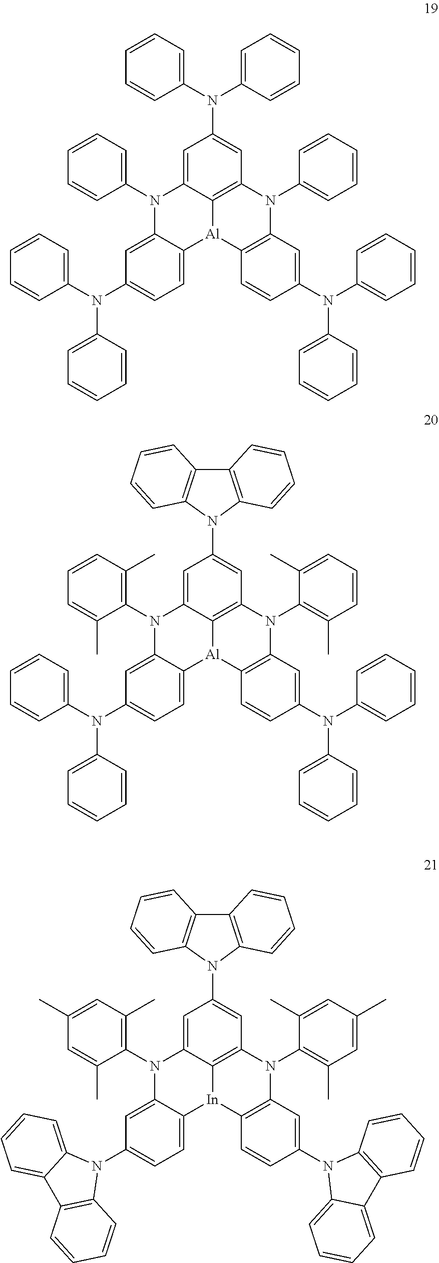 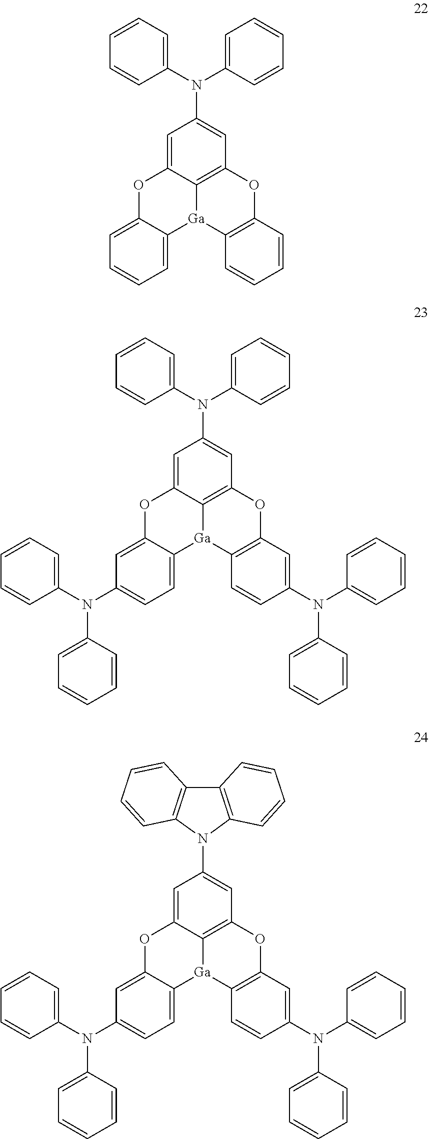 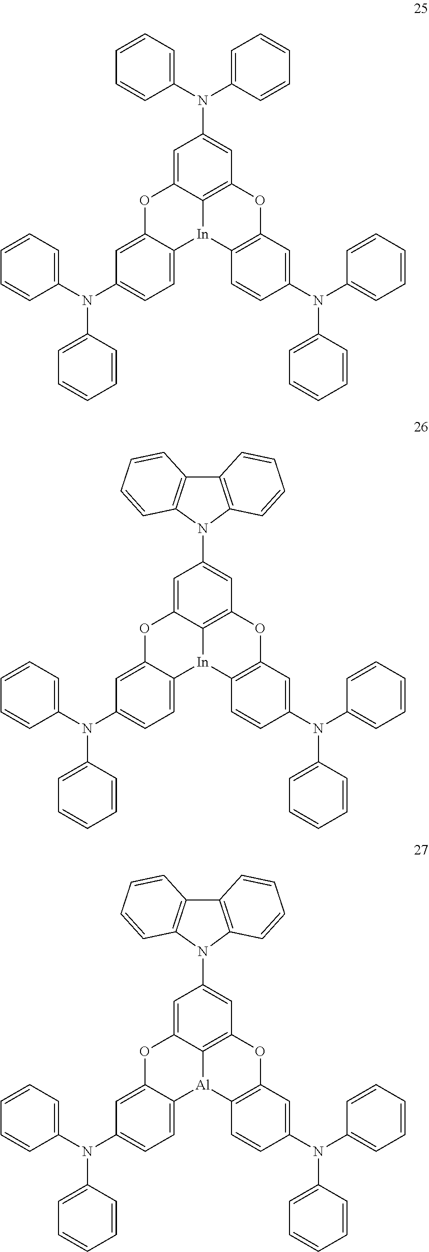 [chemical structure]
